(19) United States
(12) Patent Application Publication
(10) Pub. No.: US 2024/0429049 A1
(43) Pub. Date: Dec. 26, 2024

(54) PLANARIZATION OF ROUGH SURFACES

(71) Applicants: Alliance for Sustainable Energy, LLC, Golden, CO (US); Colorado School of Mines, Golden, CO (US)

(72) Inventors: Aaron Joseph PTAK, Littleton, CO (US); Anna Katherine BRAUN, Ewing Township, PA (US); Corinne Evelyn PACKARD, Lakewood, CO (US)

(21) Appl. No.: 18/754,435

(22) Filed: Jun. 26, 2024

Related U.S. Application Data
(60) Provisional application No. 63/510,166, filed on Jun. 26, 2023.

(51) Int. Cl. H01L 21/02; C30B 25/02

(52) U.S. Cl. CPC H01L 21/02538; C30B 25/02; H01L 21/02387; H01L 21/02433; H01L 21/0262

(57) ABSTRACT

The present disclosure relates to a method for smoothing a surface, where the method includes a first depositing onto a first surface of a first layer, resulting in the forming of a second layer on the first surface, where the first depositing is performed using hydride vapor phase epitaxy (HVPE). The first surface is characterized by a first surface feature height and the second layer has a second surface that is characterized by a second surface feature height that is less than the first surface feature height.

### CROSS-REFERENCE TO RELATED APPLICATIONS

This application claims priority from U.S. Provisional Patent Application No. 63/510,166 filed on Jun. 26, 2023, the contents of which are incorporated herein by reference in its entirety.

### CONTRACTUAL ORIGIN

This invention was made with government support under Contract No. DE-AC36-08GO28308 awarded by the Department of Energy. The government has certain rights in the invention.

### BACKGROUND

Despite their superior performance, the cost of III-V device production has prohibited wide-scale use of these materials in cost-sensitive markets such as terrestrial solar power conversion. The largest single contributor to the cost of III-V photovoltaic devices is the cost of the growth substrate. High-purity single crystal substrates cost between $90 and $150 per six inches of wafer at high volume, which includes multi-step chemo-mechanical polishing (CMP) that can exceed $25/polish to produce “epitaxy-ready” wafers.

Substrate reuse provides a path to reduce material costs by amortizing the cost of a single substrate over multiple device growths. However, to date, limitations of the techniques have prevented significant cost savings via substrate reuse. Epitaxial liftoff (ELO) is sometimes used in industry for substrate reuse and employs a selective wet-chemical etch that laterally removes a sacrificial aluminum arsenide layer, freeing the device layers from the parent substrate. ELO has enabled some cost savings through reuse, but it faces challenges due to low throughput caused by mass-flow limited etching and the need for additional CMP steps after device lift-off to reduce roughness and remove etch products left by the etch process. Controlled spalling is a promising high-throughput alternative to ELO that is currently being developed at the lab scale. Controlled spalling is a fracture-based technique that utilizes a stressor layer deposited on the surface of a device to help initiate and guide a lateral crack beneath the device layers with the application of an external peeling force. The drawback to substrate reuse by spalling is that the brittle fracture process can create fracture features on the substrate surface, and these features are sub-optimal for subsequent growth. For (100)-oriented GaAs substrates, the most common substrate used for III-V opto-electronic device growth, the spalling fracture produces large triangular facets with 5-10 μm peak-to-trough height because low-energy fracture planes are oriented at a high angle relative to the substrate surface. CMP to remove these features and reclaim a traditional epitaxy-ready surface would likely incur costs equal to or greater than the cost of CMP used to prepare the wafer surface after cutting from a boule and would produce significant waste material. These considerations make the facets created during spalling of (100) GaAs a substantial cost barrier to the immediate application of this technique in established industrial processes. Thus, there remains a need for methods and/or systems for producing substrates resulting from spalling and/or cutting having surfaces sufficiently smooth to enable the cost-effective synthesis of III-V devices having desirable physical properties and performance metrics.

### SUMMARY

An aspect of the present disclosure is a method for smoothing a surface, where the method includes a first depositing onto a first surface of a first layer, resulting in the forming of a second layer on the first surface, where the first depositing is performed using hydride vapor phase epitaxy (HVPE). The first surface is characterized by a first surface feature height and the second layer has a second surface that is characterized by a second surface feature height that is less than the first surface feature height. Further, the first layer is constructed using a first III-V alloy or an alloy that includes a Group IV element, and the second layer is constructed using a second III-V alloy or an alloy that includes a Group IV element.

In some embodiments of the present disclosure, the first III-V alloy may include a first Group III element that includes at least one of boron, aluminum, gallium, indium, and/or thallium, and the first III-V alloy may include a first Group V element that includes at least one of nitrogen, phosphorus, arsenic, antimony, and/or bismuth. In some embodiments of the present disclosure, the first III-V alloy may include at least one of GaAs and/or InP.

In some embodiments of the present disclosure, the second III-V alloy may include a second Group III element that includes at least one of boron, aluminum, gallium, indium, and/or thallium, and the second III-V alloy may include a second Group V element that includes at least one of nitrogen, phosphorus, arsenic, antimony, and/or bismuth. In some embodiments of the present disclosure, the second III-V alloy may include at least one of GaAs, GaInP, AlGaAs, AlInP, AlGaInP, GaInNAs, and/or GaInNAsSbBi.

In some embodiments of the present disclosure, the first surface feature height may be between 1 μm and 100 μm. In some embodiments of the present disclosure, the first surface feature height may be between 1 μm and 20 μm. In some embodiments of the present disclosure, the second surface feature height may be less than or equal to about 1 μm. In some embodiments of the present disclosure, the second surface feature height may be between 0.1 μm and 1 μm.

In some embodiments of the present disclosure, the first depositing may be performed using at least one of a first precursor that includes the first Group III element, a second precursor that includes the first Group V element, and a first carrier gas. In some embodiments of the present disclosure, the first depositing may be performed at a first pressure between 0.01 atm and 2.0 atm. In some embodiments of the present disclosure, the first depositing may be performed at a first temperature between 500° C. and 800° C.

In some embodiments of the present disclosure, the first precursor and the second precursor may be supplied to provide a first ratio of the first Group V element to the second Group III element (V/III) is between 0.1 (0.1 to 1.0) and 20 (20 to 1.0). In some embodiments of the present disclosure, the first surface may be characterized by a substrate orientation that includes at least one of a (100) orientation, a 211 orientation, or steps on spalled (110) substrate. In some embodiments of the present disclosure, the first surface may be characterized by a (100) orientation, a (111) orientation, a (211) orientation, a (311) orientation, or a (110) orientation.

In some embodiments of the present disclosure, the first surface may have an offcut between zero degrees and 30 degrees. In some embodiments of the present disclosure, the first surface may have a substantially corrugated surface that includes at least one of {n11} facets or {110} facets, where n is an integer value between 1 and 5, inclusively. In some embodiments of the present disclosure, the facets may include {211} facets.

In some embodiments of the present disclosure, the method may further include a second depositing onto the second surface of the second layer, resulting in the forming of a third layer on the second surface, where the third layer has a third surface having a third surface feature height that is less than the second surface feature height. Further, the second depositing may be performed using hydride vapor phase epitaxy (HVPE), and the third layer may include a third III-V alloy.

An aspect of the present disclosure is a composition that includes a first layer having a surface characterized by a first surface feature height and a second layer having a surface characterized by a second surface feature height, where the first layer is positioned adjacent to and in contact with the second layer, and the second surface feature height is less than the first surface feature height.

### BRIEF DESCRIPTION OF DRAWINGS

Some embodiments are illustrated in referenced figures of the drawings. It is intended that the embodiments and figures disclosed herein are to be considered illustrative rather than limiting.

FIG. 1 illustrates Nomarski optical microscopy images of fully polished, as-cut, and spalled surfaces, according to some embodiments of the present disclosure. The inset of the spalled surface image is a cross-sectional secondary electron microscopy (SEM) image of the facets formed during spalling.

FIG. 2 illustrates a schematic of a hydride vapor phase epitaxy (HVPE) reactor and the flow configurations utilized in experiments described herein, according to some embodiments of the present disclosure. Bold labels indicate the five factors used in a screening study.

FIGS. 3A and 3B illustrate representative images of substrates resulting from a screening study, which show small and large changes in the planarization metrics, according to some embodiments of the present disclosure. FIG. 3A illustrates as-cut substrates: The small change is standard run #8 and the large change is standard run #6 listed in Table 1. FIG. 3B illustrates spalled substrates: The small change is standard run #8 and the large change is standard run #12 listed in Table 1.

FIGS. 4A and 4B illustrate normal plots of significance for the statistical models obtained from a design of experiment (DoE) described herein, according to some embodiments of the present disclosure. FIG. 4A illustrates the difference in average surface roughness of an as-cut substrate after growth. FIG. 4B illustrates the percent change in peak-to-trough height after growth on a spalled substrate. Square points indicate significant factors with relative significance determined by the distance from the blue reference line.

FIG. 5 illustrates a comparison of measured change in average surface roughness (Sₐ) (before-after) to values calculated by a statistical model resulting from a design of experiment (DoE) for growth on as-cut substrates, according to some embodiments of the present disclosure. The dotted lines are included to show the shape of the tested parameter space. The calculated values are within a standard deviation of the experimental values and the shape of the parameter space is consistent between experiment and the model.

FIG. 6 illustrates a comparison of experimental % change in peak-to-trough height [(initial−final)/initial] to values calculated by the DoE model for growth on spalled substrates, according to some embodiments of the present disclosure. The dotted lines are included to show the shape of the tested parameter space. The calculated values are not within the standard deviation of the experimental values, but the shape of the parameter space is consistent between experiment and the model.

FIG. 7A illustrates representative height maps of an as-cut surface before (top) and after planarizing growth (bottom) using preferred conditions determined by the DoE analysis, according to some embodiments of the present disclosure.

FIG. 7B illustrates the line profiles (indicated by the arrows on the heat maps of FIG. 7A) comparing the height across the same area before and after growth and is normalized to the mean plane of the profile, according to some embodiments of the present disclosure.

FIG. 8A illustrates representative height maps of the spalled (100) GaAs surface before (top) and after (bottom) planarizing growth using preferred conditions determined by the DoE analysis. The arrows indicate the position of the profiles in the height maps and the heights are plotted relative to the mean plane of the scan.

FIG. 8B illustrates (top) line profiles (indicated by the arrows on the heat maps of FIG. 8A) comparing the height across the same features before and after the 7.5 min growth and (bottom) after 10.8 min of growth using the same planarization growth conditions, according to some embodiments of the present disclosure. Heights are plotted relative to the mean plane of the scan.

FIG. 9 illustrates a cross-sectional image of overgrowth on spalled (100) GaAs surfaces after 7.5 minutes of planarization growth, according to some embodiments of the present disclosure. The contrast was a result of the n/p doping in the substrate/growth.

FIG. 10A illustrates facet formation relative to offcut direction, according to some embodiments of the present disclosure. The spall direction is indicated, and the image shows that facets form with ridges perpendicular to the spall direction across the full wafer surface (facets not to scale). The expanded view indicates the typical dimensions of the facets.

FIG. 10B illustrates a confocal laser microscopy line profile of a facet formed during a [0 1̅ 1] spall, according to some embodiments of the present disclosure. The dotted lines indicate regions of {211}B and {311}B character on the facet faces, and the star indicates the approximate location of the AFM scan.

FIG. 10C illustrates an AFM scan of a faceted surface showing low roughness, according to some embodiments of the present disclosure. The scan was leveled using a plane-tilt correction due to the inclination of the facet face.

FIG. 11 illustrates cross-sectional SEM images of planarization growth, according to some embodiments of the present disclosure. Panel A) illustrates a cross-sectional SEM image that indicates the {n11}B and (100) planes visible in the cross sections and shows how the perpendicular growth rate was measured from each surface type. The image also shows the observable evolution of the {211}B/{311}B mixed-character facet face to a fully {311}B facet face. Panel B) illustrates representative cross-sectional SEM images showing how an increased planarization metric (np) results in complete planarization with less growth.

FIG. 12 illustrates trends observed in the effective growth rates on the {211}B, {311}B, and (100) surfaces as well as the planarization metric, according to some embodiments of the present disclosure: (Left) Varying GaCl flow rate. (Right) Varying AsH₃ flow rate. The error bars represent the 95% confidence interval for the average growth rate. Dashed lines are included on the growth rate plots to guide the eye.

FIG. 13A illustrates a cross-sectional SEM image of a sample grown at the GaCl=30 sccm condition (AsH₃=34 sccm) showing evidence of diffusion from the (100) surface to the facet surfaces, according to some embodiments of the present disclosure.

FIG. 13B illustrates a comparison of growth behavior on {n11}B and (100) surfaces with diffusion from the (100) surface (faceted substrate) and without diffusion (planar substrates), according to some embodiments of the present disclosure. The error bars represent the 95% confidence interval for the average growth rate.

FIG. 14 illustrates the influence of temperature on (100) and {n11} growth rates, growth rate versus temperature for (100) substrates with a 6° offcut toward (1 1̅ 1̅) and nominally exact (211)B and (311)B substrates, according to some embodiments of the present disclosure. Growth conditions: GaCl=30 sccm, AsH₃=34 sccm.

FIG. 15A illustrates a schematic of a solar cell device grown on a spalled substrate after planarization, according to some embodiments of the present disclosure. The image shows the facet features, planarization layer, and device layers, all to scale.

FIG. 15B illustrates a laser confocal microscopy height map of planarized facets after LCL layer growth on a test substrate, according to some embodiments of the present disclosure.

FIG. 15C illustrates (Panel A) the external quantum efficiency (EQE) for the device grown on a planarized spalled substrate compared to the control, according to some embodiments of the present disclosure. The differences between the planarized and control device are likely a result of different thicknesses in the device layers. There is no indication of decreased carrier diffusion and collection in the planarized device. Panel B illustrates the J-V behavior and performance metrics for the planarized and control devices. Growth on the planarized spalled surface had minimal effect on performance.

### DETAILED DESCRIPTION

The present disclosure provides methods for addressing the issue of incomplete planarization during growth on surfaces with features that have many orientations. Planarizing overgrowth offers a path to mitigate the effects of roughness on device growth by in situ smoothing of morphological features. This method exploits differences in growth rates occurring on different crystal planes to promote growth onto a surface, e.g., a (100) surface. Recovering a smooth surface via planarizing growth enables use of rough and/or reused substrates, thereby reducing and/or replacing the need for extensive ex situ preparation via CMP, potentially increasing the throughput of device production and lowering costs. As used herein, surface roughness (Sₐ) and peak-to-trough heights are examples of surface features that measure the irregularities present on a surface relative to a completely smooth, flat, featureless surface.

Planarization growth conditions favor growth on some planes more than others due to growth kinetics that result in different growth rates occurring on different planes and, as a result, targeted thickening of layers occurring on some planes, with less thickening occurring on other planes. Thus, in some embodiments of the present disclosure, a single growth condition or set of conditions, can target a small set of planes for high growth rate, resulting in elimination of those planes and a smoothing of the overall, larger-scale surface.

However, in some embodiments of the present disclosure, surfaces having a wide range of planes, such as “as-cut” wafers (i.e., wafers mechanically cut from a boule) that have not been polished, a single condition may not facilitate planarization of all features. In these cases, a single growth condition can result in the formation and/or preservation of features after some initial smoothing, resulting in the forming of a surface or surfaces unsuitable for device growth. Thus, as described herein, a multi-step planarization growth procedure, using multiple conditions, can be used to achieve planarization of features across a wider range of possible surface planes to achieve a smooth surface suitable device growth. Such a multi-step planarization process can enable use of a wider variety of lower-cost substrates for III-V epitaxy, including as-cut wafers and imperfectly spalled substrates, and minimize the need for expensive polishing steps during wafer preparation, helping reduce the overall cost of III-V device production.

As described herein, planarization was achieved using hydride vapor phase epitaxy (HVPE), a potentially low-cost III-V growth technique due to its lower cost precursors, high utilization, and high growth rates. HVPE is also potentially enabling as a planarization technology because of pronounced growth rate differences caused by differences in the kinetic limitations of growth on different crystal planes.

The effect of changing HVPE growth parameters on the evolution of two types of rough (100)-oriented GaAs substrate surfaces is described herein: as-cut surfaces and faceted surfaces resulting from spalling. A design of experiments (DoE) analysis was performed to efficiently probe the parameter space and determine growth conditions that have a statistically significant effect on the planarization of rough surfaces as a result of the deposition of material onto the rough surfaces by HVPE. The results from the DoE analysis were subsequently used to design growth conditions that favor planarization of both the as-cut morphologies and the spalled morphologies. The results therefrom show that significant planarization of initially rough surfaces can be achieved using the growth conditions identified.

### Experimental Methods:

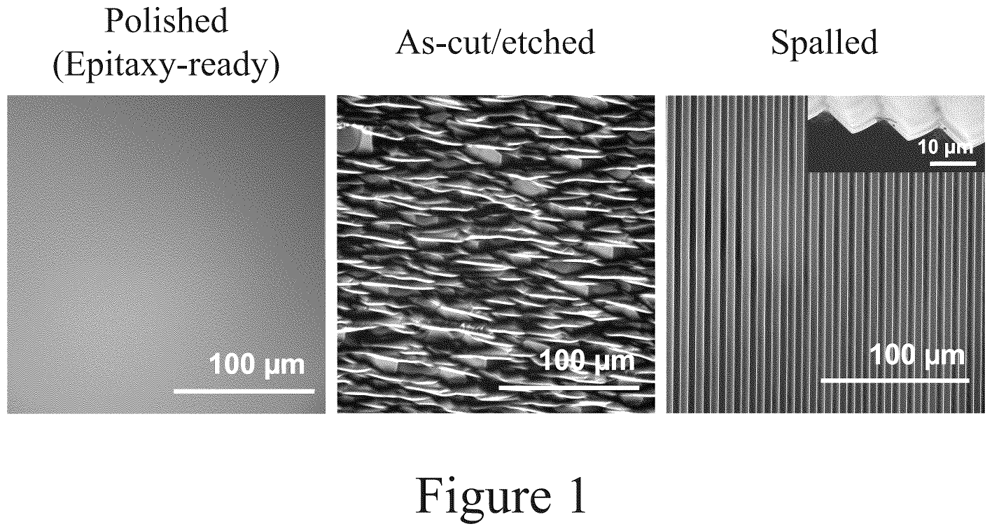

Fully polished (epitaxy ready) and as-cut (100)-oriented GaAs substrates were purchased from a commercial supplier. The as-cut substrates (not the epitaxy ready substrates) were subjected to an initial proprietary etch by the supplier after wire cutting from the boule to remove surface contamination, resulting in a surface morphology having many types of planes with feature heights between 2 μm and 8 μm in height (e.g., perpendicular to the surface of the wafer). Substrates having approximately 1 cm by 1 cm dimensions were used for the growth experiments. Controlled-spalling substrates were produced by depositing an electroplated nickel stressor layer on n-type, 50-mm diameter circular wafers then applying a peeling force in the [0−1 1] direction to propagate a lateral fracture across the wafer to generate a corrugated surface with {211}B-type facets having peak-to-trough heights between 2 μm and 5 μm. Substrates having approximately 0.5 cm by 0.5 cm dimensions were cleaved from the spalled wafers for use in growth tests. FIG. 1 illustrates micrographs of the as-cut surfaces (as received from the supplier) and spalled surfaces (completed in the lab) compared to a fully polished surface for a qualitative comparison of the morphology.

Design of experiment (DoE) was used with a definitive screening design (DSD) to determine the gas flow rates that show a statistically significant effect on planarization of as-cut and spalled surfaces resulting from deposition by HVPE. A DSD allows efficient screening of many factors, in this case the growth flows, to determine which factors have a statistically significant effect on a response variable of interest, in this case the amount of planarization of a relatively rough surface resulting from the HVPE operating conditions. The analysis, therefore, provides a statistical model that describes trends in the planarization response within the tested parameter space. Unlike other types of screening designs, a DSD statistical model can include linear terms as well as quadratic (A*A) terms and identify interactions (A*B) between independent variables, e.g., HVPE operating conditions.

HVPE growth of GaAs on “as cut” and “spalled” substrates was performed at a growth temperature of 650° C. in the hydride-enhanced growth regime. The effect of the flow rates of five gases on the growth behavior of Zn-doped GaAs were studied in the analysis:
(1) AsH₃ flow rate,
(2) HCl flow rate over the Ga metal source (producing GaCl),
(3) AsH₃ carrier gas flow rate (H₂),
(4) GaCl carrier gas flow rate (H₂), and (5) free HCl flow rate.

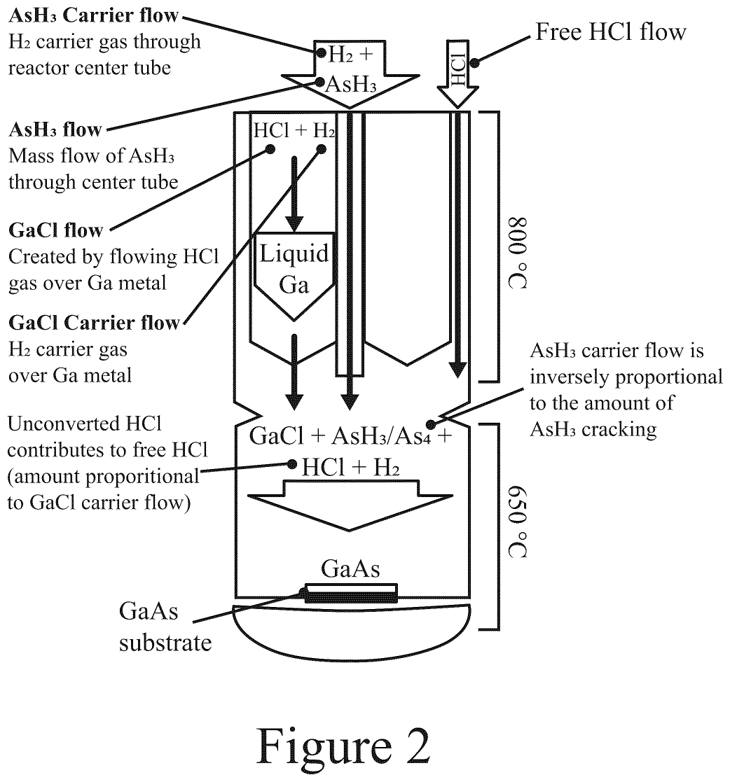

FIG. 2 illustrates the configurations of these material streams/flows to the HVPE reactor that was used to perform the DoE. These gases were chosen because they were believed to have a significant effect on growth rate on fully polished substrates utilizing HVPE and can be used to vary the partial pressure of reactants at the substrate surface, potentially affecting growth kinetics and facilitating planarization. Referring to FIG. 2, the AsH₃ flow rate can affect the amount of AsH₃ that reaches the surface, and the flow rate of HCl over the Ga metal source, henceforth referred to as the GaCl flow rate, can affect the amount of GaCl that reaches the surface. The degree of AsH₃ cracking can be proportional to the AsH₃ carrier flow rate, which can affect the Group V effective partial pressure during growth because the HVPE system was operated in the hydride-enhanced growth regime where AsH₃ is the primary active Group V species for growth. The GaCl carrier flow rate, H₂ gas, can affect the conversion of HCl to GaCl and thus may contribute to changes in both the GaCl and free HCl partial pressure during growth. The free HCl flow rate can directly affect the amount of HCl at the surface during growth, which can in turn affect the driving force for the growth reaction.

These five flows, e.g., material streams, were used as five factors in a screening study having 13 experiments and the known effects of these flow rates on the growth environment were considered in the analysis of the results. Three levels for each factor were chosen as AsH₃ flow rate: 50, 75, 100 sccm; GaCl flow rate: 5, 10, 15 sccm; AsH₃ carrier flow rate: 1000, 1750, 2500 sccm; GaCl carrier flow rate: 250, 750, 1250 sccm; free HCl: 4, 7, 10 sccm. The growth times were adjusted based on data from preliminary calibration experiments to maintain a planar growth thickness of approximately 12.5 μm across the experiments. Thickness was then treated as a covariate in the DoE analysis because it was not systematically varied and not consistent across all experiments. Details of the 13 experiments used for the analysis are listed in the first nine columns of Table 1 in the standard (non-randomized) order with the randomized experiment order indicated as well. Fully polished, as-cut and spalled substrates were co-loaded in the growth reactor for each experiment: e.g., each “run” contained three separate substrates in the HVPE reactor volume. Referring to Table 1, positive values of “% Change in spalled peak-to-trough height” represent a decrease in the peak-to-trough height, whereas negative values represent an increase. Larger values in “Change in Sₐ on as cut” represent larger smoothing affects, e.g., more planarization.

TABLE 1
Design of experiment conditions and measured changes in planarization metrics presented
in standard (non-randomized) order with non-coded units for the growth flows.*

| | | | Planar | | | | | | Change | % Change in |
|---|---|---|---|---|---|---|---|---|---|---|
| Std. | | Growth | Growth | AsH₃ | | | GaCl | Free | in Sₐ on | spalled |
| Run | Experiment | Time | Thickness | Carrier | AsH₃ | GaCl | Carrier | HCl | as-cut | peak-to-trough |
| Order | Order | (min) | (μm) | (sccm) | (sccm) | (sccm) | (sccm) | (sccm) | (nm) | height (%) |
| 1 | 5 | 4.00 | 2.3 | 1750 | 100 | 15 | 1250 | 10 | 197 ± 38 | 26.5 ± 5.8 |
| 2 | 3 | 6.92 | 1.0 | 1750 | 50 | 5 | 250 | 4 | 15.9 ± 130 | −4.43 ± 5.5 |
| 3 | 12 | 1.93 | 2.0 | 2500 | 75 | 15 | 250 | 4 | 191 ± 50 | 45.8 ± 5.7 |
| 4 | 9 | 30.0 | 2.6 | 1000 | 75 | 5 | 1250 | 10 | 165 ± 54 | 17.3 ± 5.1 |
| 5 | 11 | 2.08 | 2.2 | 2500 | 100 | 10 | 1250 | 4 | 173 ± 38 | 10.7 ± 12 |
| 6 | 13 | 14.4 | 1.2 | 1000 | 50 | 10 | 250 | 10 | 252 ± 88 | 94.3 ± 15 |
| 7 | 2 | 2.25 | 1.0 | 2500 | 50 | 15 | 750 | 10 | 148 ± 27 | 58.8 ± 16 |
| 8 | 7 | 9.40 | 1.2 | 1000 | 100 | 5 | 750 | 4 | 73.6 ± 80 | 13.1 ± 14 |
| 9 | 4 | 2.82 | 1.2 | 2500 | 50 | 5 | 1250 | 7 | 63.1 ± 27 | 47.2 ± 8.8 |
| 10 | 8 | 5.12 | 0.9 | 1000 | 100 | 15 | 250 | 7 | 133 ± 29 | 30.4 ± 2.2 |
| 11 | 1 | 2.00 | 1.5 | 2500 | 100 | 5 | 250 | 10 | 195 ± 45 | 41.0 ± 4.6 |
| 12 | 6 | 20.3 | 1.6 | 1000 | 50 | 15 | 1250 | 4 | 202 ± 25 | 93.4 ± 4.6 |
| 13 | 10 | 5.07 | 1.3 | 1750 | 75 | 10 | 750 | 7 | 72.0 ± 32 | 18.5 ± 5.9 |

*Growth time was adjusted to achieve a growth thickness between 0.9 μm and 2.6 μm and was not a systematically varied factor in the design.

The as-cut and spalled substrates were analyzed with laser confocal microscopy in the same approximate location before and after growth to quantify the change in surface morphology due to the overgrowth. Different roughness metrics were used to track planarization on the as-cut and spalled substrates due to their morphological differences. The statistical difference in the average surface roughness (Sₐ) was used to quantify planarization on the as-cut surfaces because the features on the as-cut surface are irregular. Sₐ gives a measure of the average feature size compared to the mean plane (which corresponds to the average height over the measurement area and surface roughness (Sₐ) are departures from that average height) and the change indicates how much the average feature changed in height after growth without a dependence on the orientation of the measurement with respect to the feature. The statistical percent change in peak-to-trough height after growth (i.e., the statistical difference in peak-to-trough height divided by the initial peak-to-trough height) was used to quantify the planarization on the spalled substrates. Peak-to-trough height was chosen as opposed to surface roughness (Sₐ) because the spalled surface has a regular corrugation that can be profiled for direct measurement of the amount of planarization.

Surface roughness (Sₐ) of the as-cut substrates was calculated from eighteen 286 μm×215 μm height map images taken of substrates before growth and compared to eighteen images after depositing GaAs on the starting substrates. For the spalled substrates, peak-to-trough heights were determined by averaging the height of 10 facets measured from a 2D line profile taken perpendicular to the facet peaks in the same location before and after growth. The statistical difference in surface roughness (Sₐ) and peak-to-trough height after growth was determined using a paired t-test with an alpha value of 0.05 (associated with a confidence level of 95%) for each experiment. A stepwise, non-hierarchical regression was used to reduce the model to effects that were significant with p<0.05. Next, favorable planarization growth conditions were determined for the as-cut and spalled surfaces based on the trends identified by the DoE models to evaluate the planarization achieved and the predictive capability of the models.

### Results

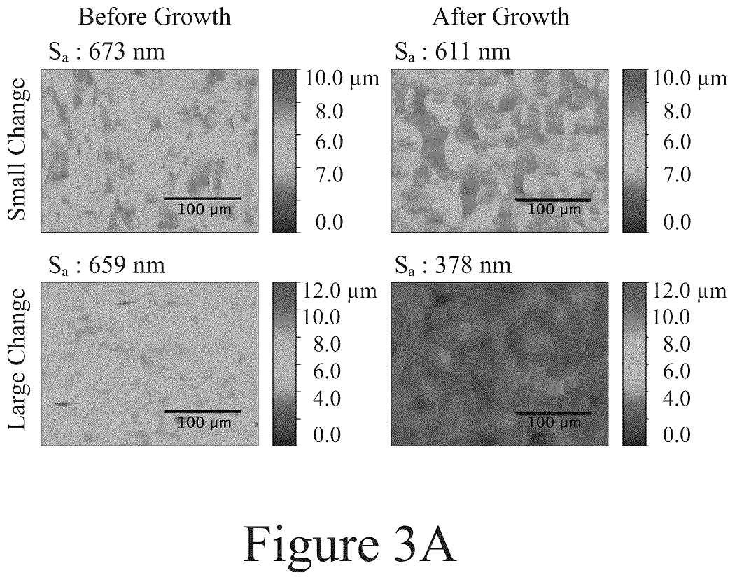

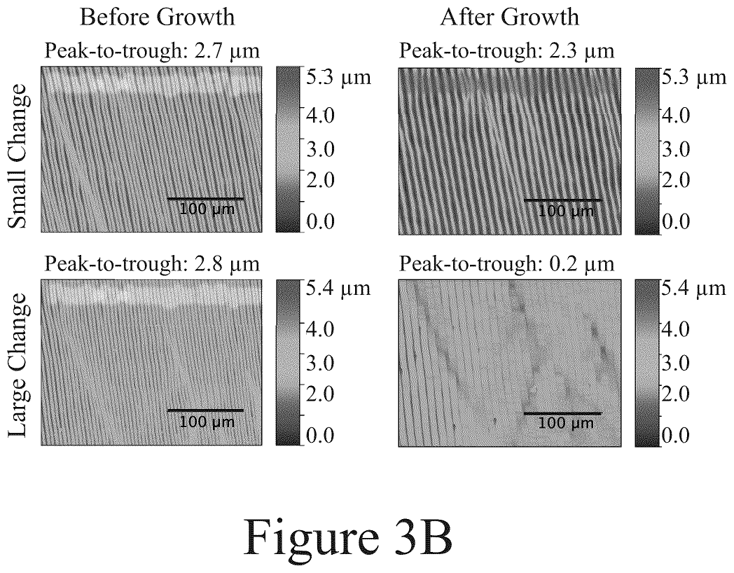

Design of Experiment Analysis: FIG. 3 illustrates representative confocal height maps taken before and after growth on as-cut and spalled GaAs substrates that demonstrate the range of planarization observed within the design space of the experiments. The statistical differences in surface roughness, Sₐ, and percent changes in peak-to-trough height measured for each experiment are also included in the last two columns in Table 1. The change in the planarization metrics was statistically significant for all experiments except for Standard Run #2 (see Table 1), which resulted in nearly conformal growth on both substrate types, such that the newly added material replicates the shape of form of the starting substrates.

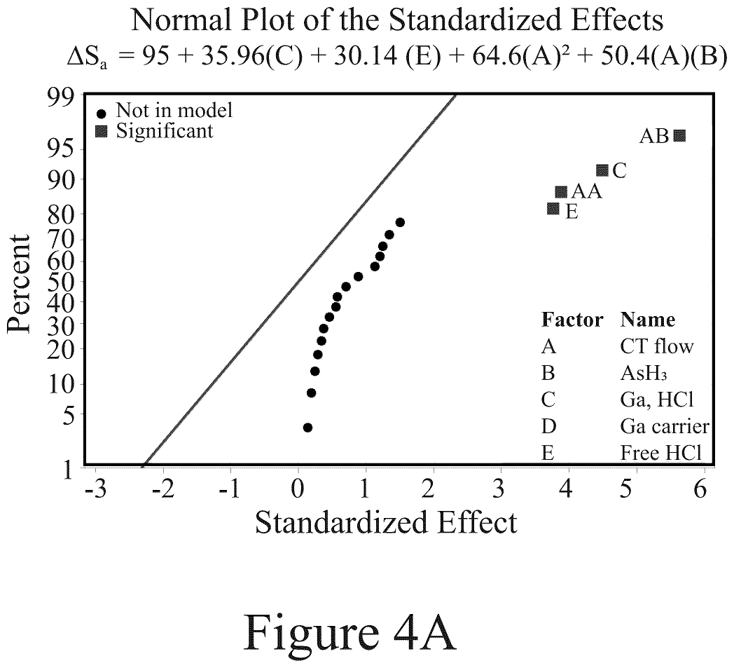

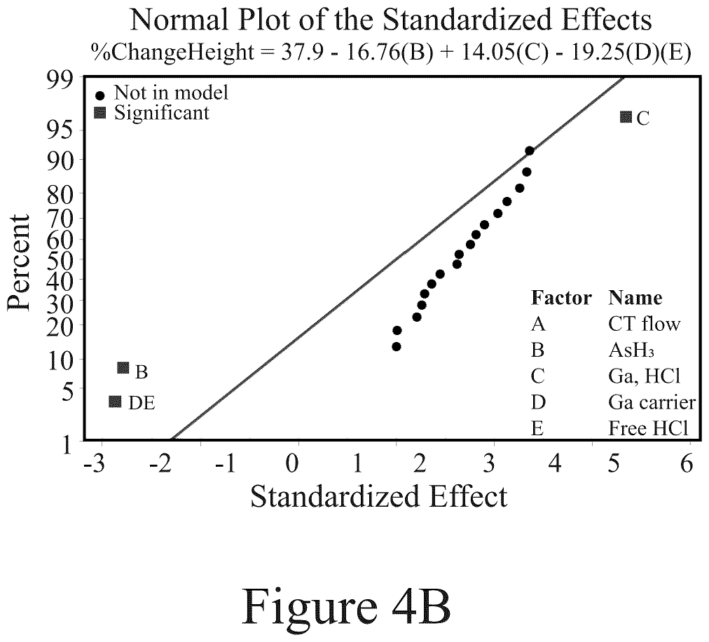

A stepwise regression analysis was used to generate a model equation describing the behavior of the response variable over the tested parameter space from the response data (see Table 1). FIG. 4 illustrates the normal plots of significance and model equations with factors in coded units (value of the flow rate normalized to a scale of −1 to 1 with reference to the limits used in the design) for the as-cut and spalled substrates. The solid line in the normal plots represents a reference case where no factors have a significant effect on the planarization metric, and factors identified to have a significant effect are indicated by square points. The round points are factors that do not have a significant effect on the planarization metric. The relative significance of a factor is indicated by the distance from the reference line, and factors with a positive correlation to the planarization metric appear on the right side of the reference line while factors with a negative correlation appear on the left side.

Referring to the top panel of FIG. 4, the model for the growth on the as-cut substrates illustrates the following. There are two interactions that decrease roughness due to the interaction and quadratic terms: 1) using a high AsH₃ carrier and high AsH₃ flow rate, and 2) using a low AsH₃ and low AsH₃ flow rate. For both cases, increased GaCl and free HCl flow rates will also decrease the roughness, with GaCl having a larger affect.

Referring to the bottom panel of FIG. 4, the model of growth on spalled substrates illustrates that the factor that has the largest influence on smoothing is an interaction between two variables, thus it has two possible instantiations that both decrease facet height: 1) increasing free HCl while decreasing GaCl carrier flow rate, or 2) decreasing free HCl while increasing GaCl carrier flow rate. Listed in order of importance, two other factors influence facet height: decreasing AsH₃ flow decreased facet height. Increasing GaCl flow decreased facet height.

The growth thickness was included as a covariate in the regression analyses but was not included in the model equations because the effect was not significant (p>0.05) in the regression analysis. It may be expected that thickness may have an effect on the final degree of planarization, i.e., the total volume of growth will affect the total amount of planarization; however, the approximately 1.7 μm variation in thickness was not large enough to observe a significant effect for the 2-8 μm sized features on the as-cut and spalled surfaces used in these experiments.

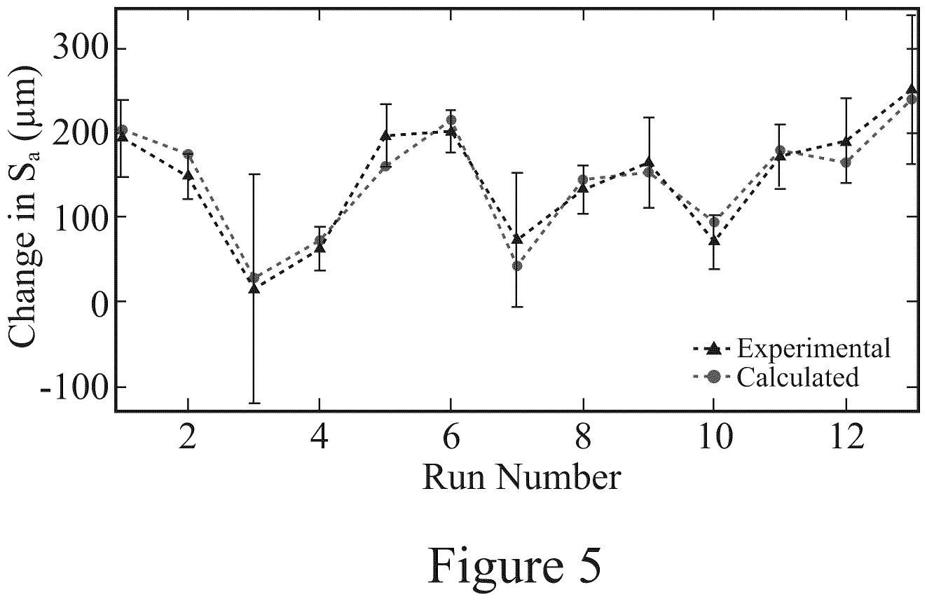

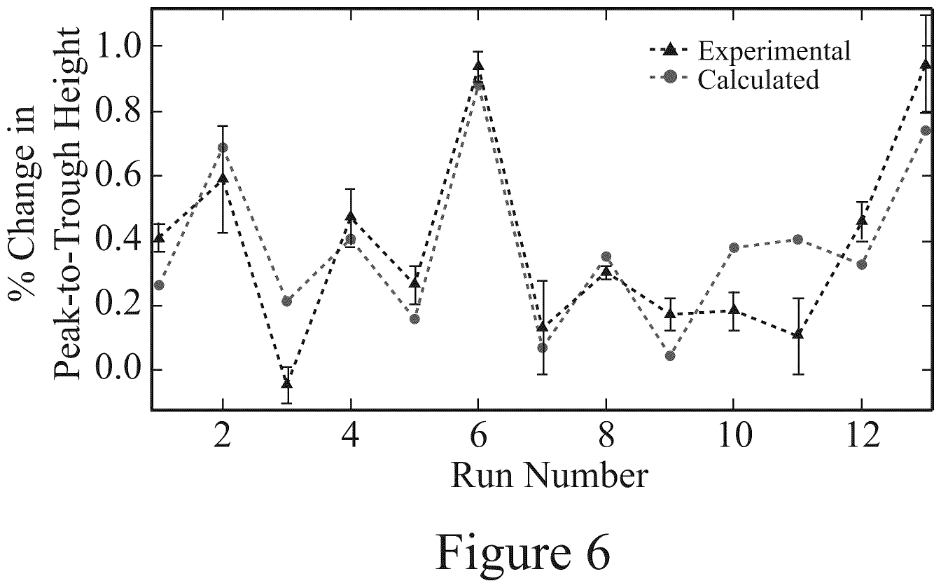

The values predicted by the statistical models to experimental values obtained in the design were compared to evaluate the quality of the regression fit throughout the test space and determine potential deficiencies in the predictive ability of the models. The model for growth on the as-cut substrates was within the standard deviation of measurement of the experimental values for change in Sₐ (see FIG. 5), indicating the regression equation fits all areas of the parameter space within the tested limits of flow rates well. This agreement also suggests the model may hold for limited excursions beyond the tested bounds, with appropriate care. The model for growth on spalled substrates was not within standard deviation of measurement of the percent change in peak-to-trough height for all experiments (see FIG. 6), but the general shape of the model was consistent with the experiment results. Further, the largest disagreements were with conditions that return a small change in peak-to-trough height, which are not of interest for planarization, so the model is appropriate for guiding design of planarization conditions that result in large changes in peak-to-trough height and facilitate planarization.

The growth models indicate two potentially favorable growth conditions that facilitate planarization for both the as-cut and spalled surfaces because of the presence of significant quadratic and two-factor interaction terms. Conditions with (1) low AsH₃ carrier and AsH₃ flow rates and high GaCl and free HCl flow rates or (2) high AsH₃ carrier, AsH₃, GaCl, and free HCl flow rates facilitate a large decrease in Sₐ and significant planarization after growth on an as-cut surface. On a spalled surface, conditions with high GaCl flow rates, low AsH₃ flow rates and either (1) high GaCl carrier with low free HCl flow rates or (2) low GaCl carrier with high HCl flow rates result in a large degrease in peak-to-trough height and significant planarizing after growth on a spalled substrate.

The faceted morphology of spalled surfaces may only have low-energy {211}B-type planes. The favorable planarization growth conditions for such surfaces were identified with a high GaCl flow rate and a low AsH₃ flow rate, indicating that a low V/III ratio is beneficial to planarization growth on the low-energy facet planes. An effect of HCl partial pressure through the interaction of the free HCl and GaCl carrier flows was also observed. The negative correlation of the two-factor interaction term in the DoE model implies a concave curvature in the planarization response relative to the HCl partial pressure, meaning a mid-level HCl partial pressure, corresponding to an HCl concentration in a range between 500 ppm and 1,000 ppm.

In contrast to the results on the spalled surface, the model for growth on the as-cut surface indicates multiple regimes that can facilitate planarization because the as-cut surface exposes a wide range of planes. The first planarization condition for the as-cut surface correlates to a high GaCl flow rate, low AsH₃ flow rate, and low AsH₃ carrier flow rate, which further reduces the active Group V partial pressure at the surface through AsH₃ cracking. This condition is consistent with the low V/III ratio regime that facilitates planarization on low-energy surfaces, as observed on the spalled surfaces. The second growth condition (high AsH₃ carrier, AsH₃, GaCl, and free HCl flows) indicates a higher V/III ratio achieved with higher partial pressure of uncracked AsH₃ can be beneficial to planarization if the partial pressure of GaCl remains high as well. This higher V/III ratio condition implies another regime for planarization that is more effective on higher-energy planes that are exposed on the as-cut surface and was thus not observed in growth on the spalled surface. Additionally, the effect of AsH₃ cracking observed in the as-cut growth model was not observed in the analysis of growth on the spalled surface, which implies the degree of AsH₃ cracking was not as significant for growth on low-energy surface morphology. High HCl partial pressure was beneficial in both planarization growth conditions for the as-cut surface, which also contrasts with the implied quadratic effect of HCl observed on spalled surfaces. This difference may be attributed to the presence of higher energy planes on the as-cut surface that affected the sensitivity to changes in growth-rate hierarchy resulting from the HCl partial pressure and thus affected the planarization growth behavior.

Testing Planarization Conditions Designed using DoE Guidance: Next, the conditions favorable for substrate planarization identified by the DoE were evaluated to determine the amount of planarization achieved after about 7.5 minutes of growth by HVPE. For growth on as-cut GaAs substrates, growth conditions with high AsH₃ carrier flow rate and high AsH₃ flow rate for growth was tested because using low AsH₃ carrier and AsH₃ flow rates significantly lowers growth rate which is unfavorable for throughput and potential cost savings. For growth on spalled GaAs substrates, the growth condition with high GaCl carrier and low free HCl flow rate was tested. The flow rates that did not have a significant effect on planarization were set as follows: for the as-cut substrates, the GaCl carrier flow rate was set to the high level used in the DoE analysis and for the spalled substrates, the AsH₃ carrier flow was set to the high level used in the DoE analysis.

Table 2 summarizes the growth conditions used for each substrate, as well as the growth thickness measured from a fully polished substrate co-loaded in the run. The growth thickness on the polished substrate gave a reference for the growth rate on a consistent surface between conditions because the growth rate is dependent on the surface planes exposed, making direct comparison between the as-cut and spalled surfaces difficult. The models determined in by the DoE assumed a thickness of at most 2.6 μm because that was the maximum thickness observed in the experiments and the effect of thickness was not quantifiable as part of the model. To establish expectations for planarization using greater than 2.6 μm of growth, a positive trend in planarization with growth thickness was assumed because there is more material that can contribute to smoothing the surface morphology. The model for growth on as-cut surfaces predicted a 276 nm decrease in Sₐ with this growth conditions so a >276 nm reduction in Sₐ was expected in this test due to the higher thickness of growth (5.6 μm). The model of growth on spalled surfaces predicted an 88% decrease in peak-to-trough height with the designed planarization condition in 2.6 μm of growth. A similar reduction in peak-to-trough height with this 7.5 min growth test may be expected because it achieves 2.6 μm of growth.

TABLE 2
Growth conditions tested based on DoE results.

| | Planar | AsH₃ | | | GaCl | Free |
|---|---|---|---|---|---|---|
| | Growth | Carrier | AsH₃ | GaCl | Carrier | HCl |
| Substrate | Thickness* | (sccm) | (sccm) | (sccm) | (sccm) | (sccm) |
| As-cut | 5.6 μm | 2500 | 100 | 15 | 1250 | 10 |
| Spalled | 2.6 μm | 2500 | 50 | 15 | 1250 | 4 |

*Measured from a co-loaded planar substrate

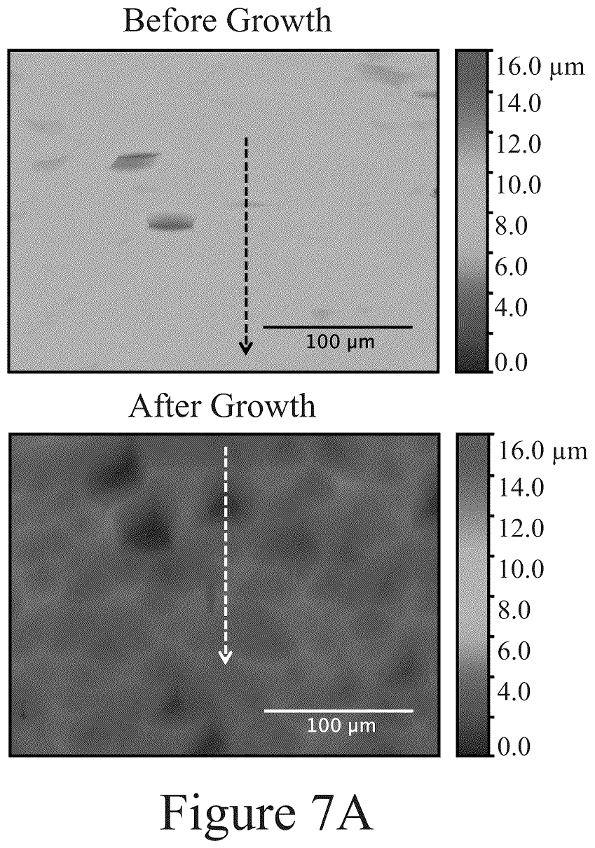

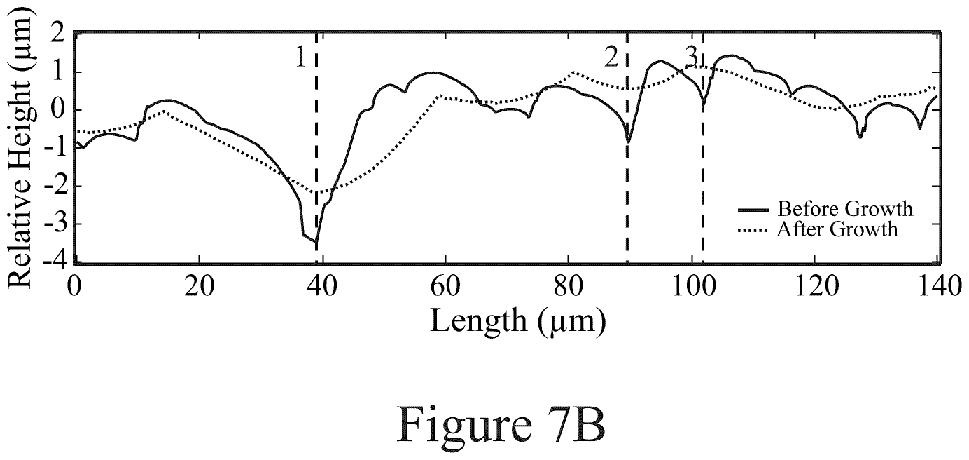

Planarization achieved on an as-cut substrate was evaluated first, using the growth conditions summarized in Table 2. FIG. 7 illustrates representative confocal microscopy height maps of the same region on the as-cut substrate surface before and after planarizing growth as well as a comparison of line profiles over the same area before and after growth, with heights plotted relative to the mean plane of the line scan. The average surface roughness decreased from 658 nm to 499 nm (159 nm, 24% decrease) over a 286 μm×215 μm area, which is evident by the change in color distribution in the height maps. The line profile shows over 2 μm in feature height reduction for the largest feature (position 1) in the line profile. There was also more than a 2× reduction in the number of peaks in this line scan after growth and the gradient of the feature shapes was reduced, but some sharp peaks remained after growth.

These growth conditions used a higher V/III ratio regime, for example, at a ratio greater than 5:1 or between 5:1 and 10:1 that was expected to favor smoothing on high-energy planes, and the observed changes in the morphology showed evidence of elimination of high-energy planes in favor of lower-energy planes during the planarization growth. Troughs with steep slopes, like the trough before growth at position 1 (see bottom panel of FIG. 7), likely exposed high-energy planes that were favorable for fast growth in this planarization condition. The growth rate differences achieved with these growth conditions then resulted in elimination of fast-growing planes and evolution of those features to only expose lower-energy planes that have a shallower slope. Peaks formed where the evolved lower-energy surfaces met. Coarsening of the lateral feature size was also observed, which contributed to planarization through elimination of small features. Finally, an effect was observed of growth rate differences on the final location of the peaks relative to the initial surface when steep troughs were close together, such as at positions 2 and 3 in the profile (see bottom panel of FIG. 7). Growth rate differences affected the rate at which one trough filled relative to the other and, thus, where the evolved lower-energy surfaces met, resulting in misalignment of the peaks between the before and after growth profiles.

While there was a 159 nm decrease in Sₐ after planarization growth, the improvement was less than expected based on the DoE's statistical growth model and the assumption of increased planarization with increased thickness. This result using a higher growth thickness showed that the assumption of a positive trend in planarization with growth thickness on as-cut surfaces was incorrect and illustrated a significant and negative effect of growth thickness on the total degree of planarization of as-cut GaAs substrate surfaces. The negative effect of growth thickness on planarization may be attributed to the randomness of the as-cut surface, i.e., the as-cut surface exposes a large range of planes, and this growth condition was likely not suited for planarization over that whole range. This effect resulted in some initial planarization but also resulted in preservation of peaks and troughs that prevented full planarization as growth continued. The initial smoothing effect was captured in the DoE model, and evidence was observed of the effect in this experiment with the evolution to lower-energy, gradually sloped surfaces in areas initially having steep profiles as well as coarsening of the lateral feature sizes. A lower V/III growth condition (a lower ratio of V feed rate to III feed) was more favorable for growth on the lower-energy surfaces exposed after the initial elimination of the fast-growing planes, so the peaks formed at their intersection were preserved as the growth continued.

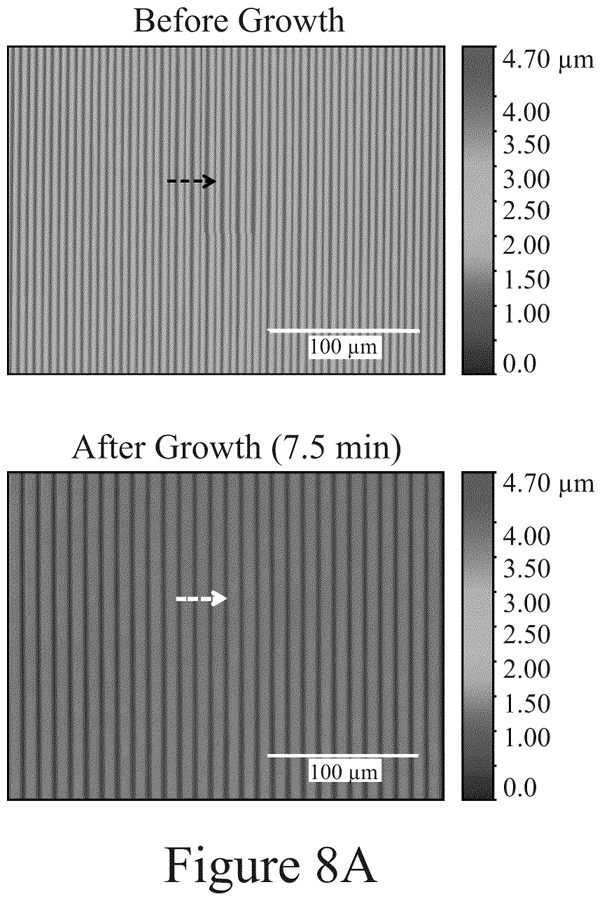

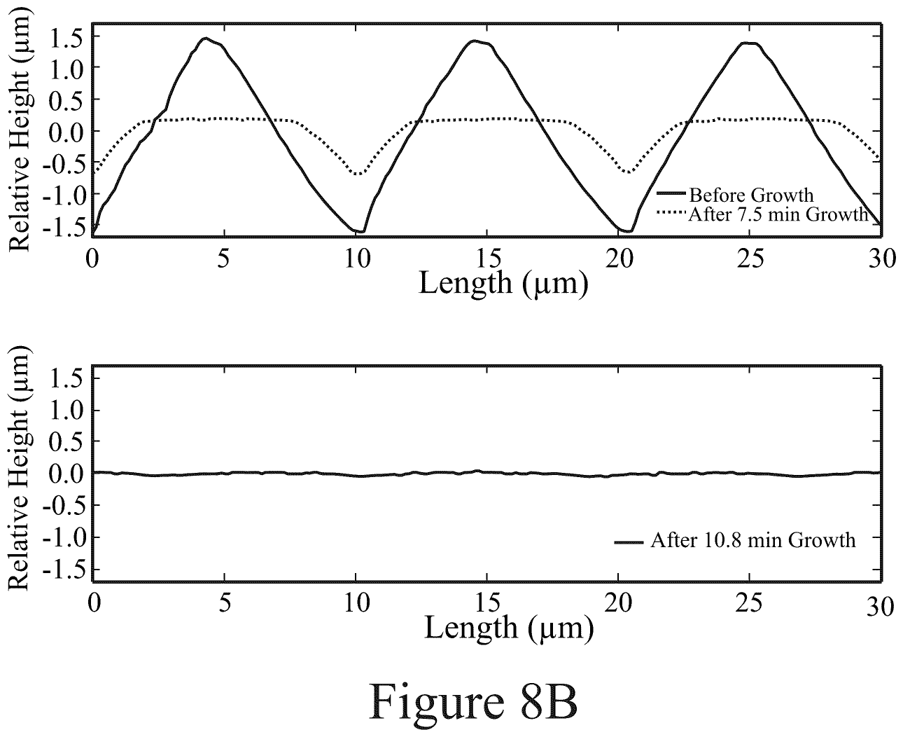

Next, the growth on a spalled substrate was analyzed using the planarization conditions summarized in Table 2. FIG. 8a illustrates confocal microscopy height maps of the spalled GaAs substrate surface and a comparison of line profiles over the facets before and after the 7.5 min planarization growth, with heights plotted relative to the mean plane of the line scan. A 70% reduction in peak-to-trough height was observed after growth, which was within 18% of the predicted change in peak-to-trough height from the statistical model. It is noted that there were two experiments in the DoE that had a larger percent change in peak-to-trough height than measured for this designed growth condition: standard run #12 (see Table 1) with a 93% change and standard run #6 (see Table 1) with a 94% change. These higher-performing conditions, and the fact the model was not within standard deviation of the experimental values of the DoE, indicate there is an effect that was not captured by the model. Factors such as variation in facet height or the variation in growth thickness do not explain this difference in planarization performance. The growth conditions for these experiments were consistent with the trends in GaCl, AsH₃, GaCl carrier, and free HCl flow rates identified by the DoE as favorable for planarization, but they also used a low AsH₃ carrier flow rate (1000 sccm opposed to 2500 sccm used in the designed condition). The effect of AsH₃ carrier flow rate was not a significant factor identified by the DoE, but factors including the AsH₃ carrier flow rate influenced the interaction term between GaCl carrier flow rate and free HCl flow rate due to the structure of the DoE.

The line profiles in FIG. 8a illustrate there was significant formation of a (100) surface at the facet peak after 7.5 minutes of growth, which is promising for full planarization. The formation of the (100) surface shows that the (100) plane was the slow-growing plane in this growth condition, and the growth proceeded without formation of alternative planes, indicating a longer growth should result in the formation of a continuous (100) surface, not perpetuation of features that inhibit planarization as observed with growth on the as-cut surface. FIG. 8b illustrates that the formation of a continuous (100) surface with a longer (10.8 min) growth was indeed observed. There were some residual features after planarization with a period that mirrors the original facet surface, but the features were shallow (<75 nm tall) and the steep angle of the original facets was eliminated. The root mean square (RMS) roughness of this surface was 24.5 nm (Sₐ=19.4 nm) across a 286 μm×215 μm area.

These results demonstrate that planarization overgrowth by HVPE is a promising technique that may enable device growth on spalled surfaces without need for ex situ CMP steps. The trends in growth behavior determined by the DoE and the understanding of the growth processes enabling planarization built from this study are also beneficial to other applications that require control of the overgrowth morphology to achieve a desired structure. The planarization conditions demonstrated here had a relatively low planarization efficiency, i.e., the growth rate anisotropy differences between the (100) surface and the facet surface was small, and a larger growth volume may be needed to achieve a fully planarized surface.

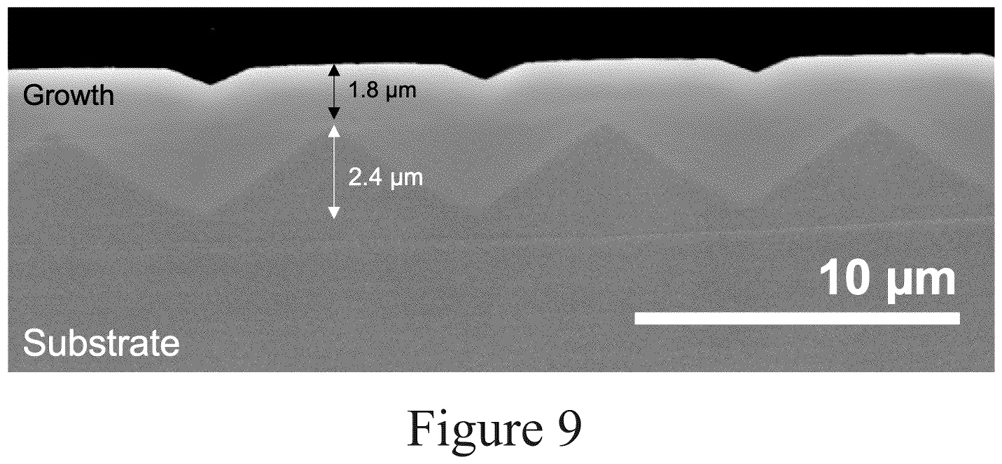

FIG. 9 illustrates a cross-sectional SEM image of the overgrowth on the spalled surface after 7.5 min of growth. There was approximately 1.8 μm of vertical growth above the 2.4 μm facet, indicating a substantial amount of the deposited material is contributing to growth on the (100) surface and not contributing to planarization. The model determined by the DoE analysis can guide further improvements of the planarization substrates, beyond the conditions initially tested, with appropriate consideration of known growth kinetic processes, to design growth for fast planarization with minimal growth volume. These next steps in growth conditions will also improve the potential economic viability of this process by improving the throughput and minimizing the materials usage for a planarizing growth step.

### Additional Work Including Complete Solar Cell Devices:

Additional work was done to evaluate the affects of GaCl and AsH₃ flow rates and compare the observed growth rate trends with those caused by HVPE growth mechanisms to determine the governing processes for planarization. In addition, it was established that material quality is maintained after planarization by demonstrating a high-performance solar cell device grown directly on a planarized spalled surface that shows near-parity performance to growth on an epitaxy-ready surface.

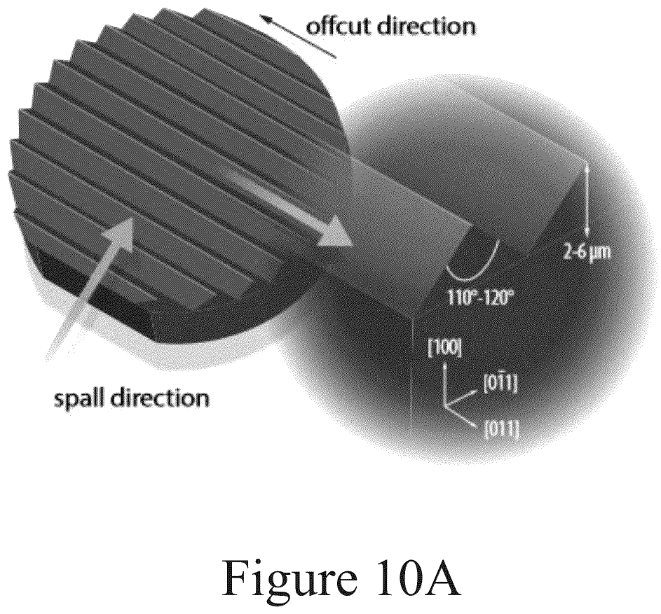

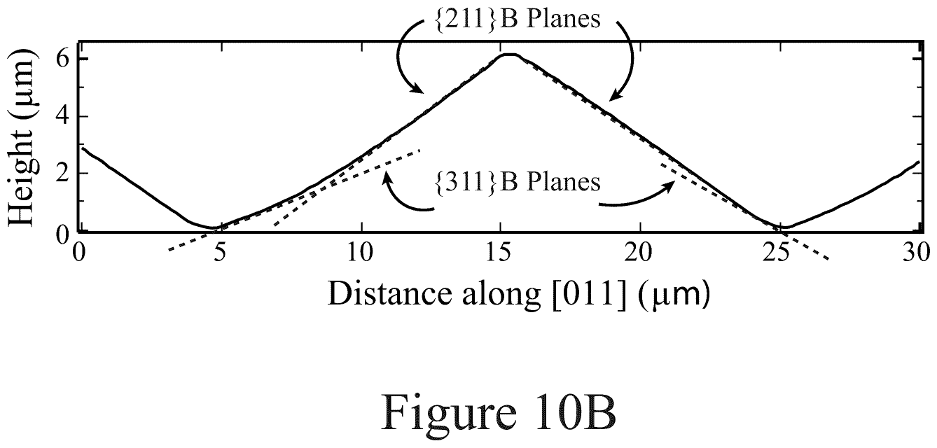

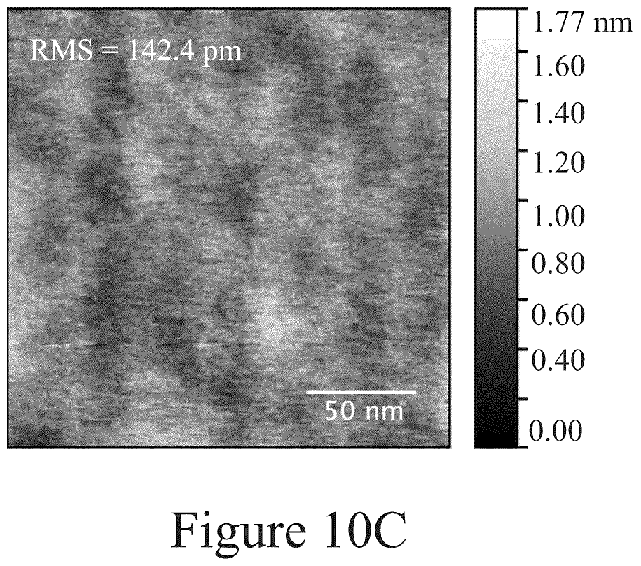

Analysis of Facet Morphology: 2 inch, (100)-oriented GaAs circular substrates were spalled with a 6° offcut toward the Ga-terminated (1 1̅ 1̅) A plane. The resulting faceted surfaces were then analyzed using confocal laser microscopy and atomic force microscopy (AFM) to understand the surface morphology available for growth. The [0 1̅ 1] spall direction was used for all growth studies in this work, producing {n11}B-type facets, where n may be integer values between 1 and 5, inclusively. FIG. 10a diagrams the spall direction relative to the wafer specifications and the resultant facet orientation. The facets form ridges with peaks and troughs oriented perpendicular to the spall direction, and the peak-to-trough heights vary from ˜2-6 μm with the stressor layer conditions used in this study (see FIG. 10b). With this spall orientation, the intentional wafer offcut direction is parallel to the facet ridges and perpendicular to the facet faces, meaning the offcut tilt is accommodated along the facet faces. FIG. 10b illustrates a confocal laser microscopy profile of the {n11}B-type facet morphology and indicates transitions from a near-{211}B surface to a near-{311}B surface at the trough on both sides of the facet, which is marked by dashed lines on the line profile. FIG. 10c illustrates a tilt-corrected AFM scan of the facet surface that has a root mean square (RMS) surface roughness of 142.4 pm over the 200-nm×200-nm area. The approximate relative location of the AFM measurement is indicated in FIG. 10b with a star. Larger-scale morphological defects were not observed.

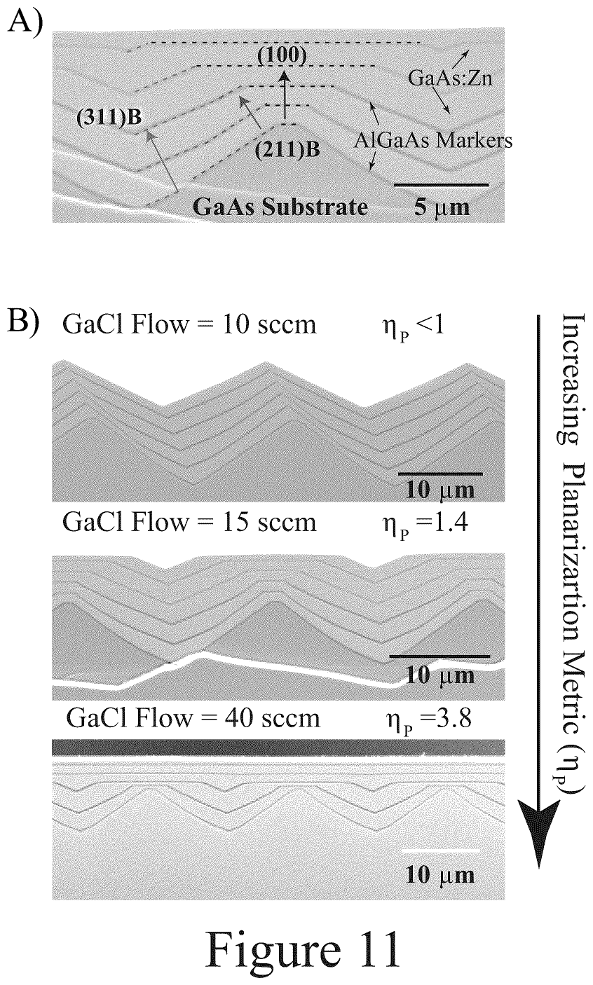

Analysis of Growth Behavior: Next, GaCl and AsH₃ flow rates were independently varied to study their effects on the growth rates of the facet planes compared to the (100) surface and to understand the kinetic processes that facilitate planarization. For each condition, five 1 μm to 2 μm thick GaAs planarizing layers were grown on the spalled surfaces separated by thin (˜70-150-nm), nearly-lattice-matched AlGaAs marker layers that allowed growth progression to be tracked. The GaCl and AsH₃ flow rates were varied in the GaAs layers between 10 sccm and 50 sccm and 17 sccm and 50 sccm, respectively. Table 3 lists the growth conditions. The AlGaAs marker layer growth conditions were not varied, and the layers did not contribute significantly to planarization due to their small thickness. FIG. 11a illustrates a cross-sectional scanning electron micrograph of a spalled GaAs substrate with planarizing HVPE growth. The image also highlights individual {211}B, {311}B, and (100) planes that appear in the cross-sectional images using colored lines, and arrows indicate how the growth rate was measured perpendicular to each of these planes. Clearly, there is an evolution during growth from a primarily {211}B-type facet plane to a fully {311}B-type plane, indicated by the dashed lines and the elimination of the kink in the facet face as growth proceeds. This evolution was observed under all conditions. The reentrant nature (i.e., inward pointing or concave) of the intersection between these {n11}B planes thus results in elimination of the lower growth rate, low-n planes in favor of the higher growth rate, high-n planes.

TABLE 3
Growth conditions used for studies of the effect of
GaCl and AsH₃ flow rates on {n11}B and (100)
growth rates with corrected mass flow controller flow rates.

| | GaCl Flow Rate | AsH₃ Flow Rate |
|---|---|---|
| Experiment | (sccm) | (sccm) |
| Effect of | 10, 15, 20, 30, 40, 50 | 34 |
| GaCl | | |
| Effect of | 20 | 17, 34, 50 |
| AsH₃ | | |

To quantify the improvement in planarization efficiency, a planarization metric was defined, η_{P}, using the measured growth rates:

$${η}_{P} = \frac{{R}_{G , \{ 211 \} B} + {R}_{G , \{ 311 \} B}}{2 * {R}_{G , ( 100 )}} \qquad ( 1 )$$

R_{G} represents the growth rate perpendicular to an indicated plane. For efficient planarization, i.e., minimal vertical growth required to restore a flat surface, η_{P} should be a large value. A large η_{P} indicates that the facet plane growth rates are significantly larger than the (100) growth rate. This metric averages the {n11}B growth rates and assumes equal weighting, as the relative contribution of growth on the {211}B versus {311}B surfaces cannot be reliably extracted for weighting within the resolution of our growth layers. It is noted that η_{P} is thus a conservative estimate of the planarization efficiency because the evolution of the facet plane to the faster-growing {311}B surface is not fully described. FIG. 11b illustrates representative cross-sectional SEM images that illustrate the range of η_{P} observed using different growth conditions. The top image uses a GaCl flow of 10 sccm has η_{P}<1 because the (100) growth rate is higher than the {n11} growth rates, resulting in conformal growth and no evolution of the (100) plane. The images of the GaCl=15 and 40 sccm conditions illustrate the effect of increasing η_{P}, from 1.4 to 3.8. The high η_{P} results in fast evolution of the (100) surface above the facet peaks and decreasing growth thickness for planarization.

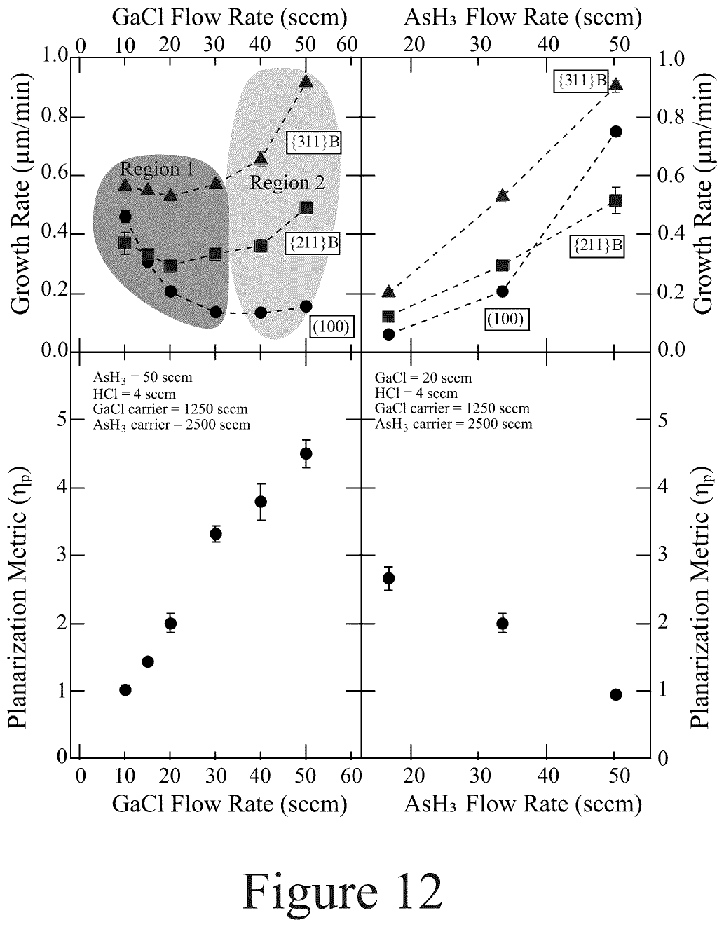

FIG. 12 (left) illustrates the trends in the measured growth rates and η_{P} with varying GaCl flow rates. It is noted that the (100) growth rate reported for the GaCl=10 sccm condition is the layer thickness measured vertically at the facet peaks (see FIG. 11b) and likely underestimates the growth rate (and likely overestimates η_{P}) at these conditions. There was a significant decrease in the (100) growth rate at GaCl flow rates between 10 sccm and 30 sccm, whereas the {n11}B growth rates had no significant change in this flow rate range (denoted as Region 1 of FIG. 12). This behavior facilitates planarization by increasing the difference in growth rate between the facet planes and the (100) surface and is reflected in the increase in η_{P}. Between GaCl flow rates of 30 sccm and 50 sccm (Region 2 of FIG. 12), the facet plane growth rates increased while the (100) growth rate remained constant and low. η_{P} shows continued improvement because the growth rate differences continued to increase. FIG. 12 (right) illustrates that varying the AsH₃ flow rate changes the growth rate on all planes. It was observed that a low AsH₃ flow rate increased η_{P} but significantly decreased the overall growth rate. Conversely, a high AsH₃ flow rate increased the growth rate on all planes but resulted in a low η_{P} because the percent change of the (100) growth rate was larger than that of the {n11}B growth rates. This effect minimizes the growth rate differences that enable planarization.

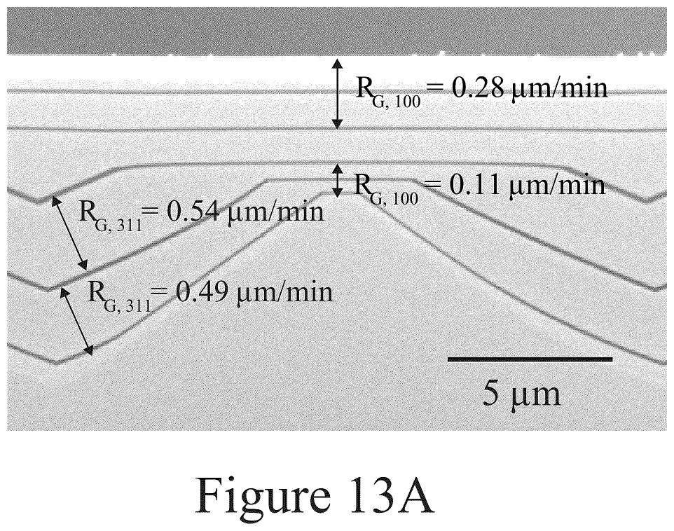

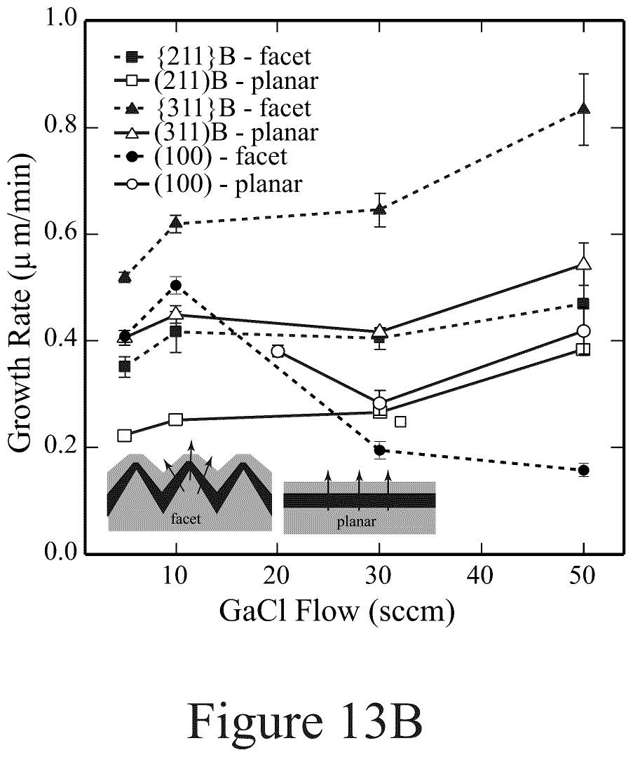

These studies of the growth behavior also revealed the effects of diffusion on the planarization behavior. FIG. 13a illustrates a cross-sectional SEM image of planarizing growth using GaCl=30 sccm and AsH₃₌₃₄ sccm. The growth rate of the (100) surface in planarizing layers is lower than in planar layers where the triangular troughs from the facets have been eliminated despite the absence of changes in growth flows. The growth rate on the {311}B facet plane also increased as planarization progressed and the (100) surface widened. Morphology-dependent growth rate suggests that the facet surfaces act as a sink for the GaCl and AsH₃ that diffuse from the (100) surface and that this diffusion contributes to the growth rate differences that enable planarization. Whether the diffusion is driven by surface diffusion or gas-phase diffusion of precursors desorbed from (100) surfaces toward the facet faces is not discernible from this study.

The growth rate behaviors on exactly oriented, planar (211)B and (311)B substrates were also studied, as well as a planar (100) substrate with a 6° offcut toward (111) A, to deconvolute the effect of diffusion from the other kinetic mechanisms that contribute to planarization. FIG. 13b compares the effect of varying the GaCl flow rate between growth on these planar substrates and growth on faceted substrates, using the same growth conditions for both substrate types. The growth rate trends observed on the planar substrates with varying GaCl are like those observed on faceted substrates. This indicates that these trends are a result of other kinetic mechanisms, because diffusion is not present on the planar substrates. The trend in the planar {n11} growth rate has nonlinear behavior, like that observed on the faceted substrates, that can similarly be divided into two regions: a constant growth rate from GaCl=10-30 sccm and an increasing growth rate above 30 sccm. The planar (100) growth rate trend also showed similar behavior to the (100) growth rate on the facets in the range of GaCl flow rates between 10 sccm and 30 sccm (decreasing growth rate with increasing GaCl flow rate), but the planar growth rate increased above GaCl=30 sccm rather than staying near constant. This difference suggests that the presence of the facet faces, which appear to act as a sink for diffused reactant material, affects the governing growth mechanism on the (100) surface at high GaCl flow rates. Overall, the planar {n11} growth rates are lower and the planar (100) growth rate are higher than those measured on faceted substrates. These observations provide further evidence that reactants diffuse away from the (100) surface toward the {n11} facets during planarization of facets. Thus, diffusion supports planarization by suppressing the (100) growth rate while contributing to the {n11} growth rates, especially at high GaCl flow rates.

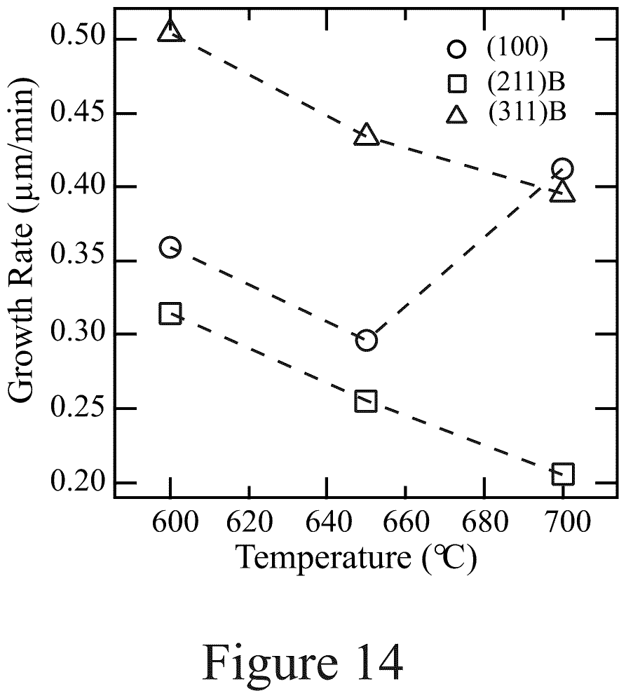

Finally, the effect of temperature on the growth rates was studied to determine the rate-limiting step to growth on each surface and to give further insight into the controlling growth mechanisms. FIG. 14 illustrates the growth rate behavior with temperatures between 600° C. and 700° C. on 6° offcut (100), exact (211)B, and exact (311)B planar substrates using GaCl=30 sccm and AsH₃₌₃₄ sccm. Both the (211)B and (311)B surfaces decrease in growth rate with increasing temperature. This trend implies that the growth reaction on the {n11}B surfaces is limited by fast desorption of reactants at this growth condition. The growth rate on the (100) plane decreased from 600° C. to 650° C. and increased from 650° C. to 700° C. This nonlinear trend indicates that the growth temperature facilitates a change in the rate-limiting growth step at these growth conditions.

Planarization Growth Mechanisms: The observed growth rate trends with changing GaCl and AsH₃ flow rates and temperature were used to determine the governing growth mechanisms that enable planarization of the spalled facets. HVPE growth proceeds via the reduction of adsorbed GaCl and the subsequent adsorption of As to form GaAs. At the growth temperature used here (650° C.), the reduction reaction occurs primarily via the “hydride-enhanced” mechanism, where GaCl is rapidly reduced by uncracked AsH₃. Simplified diagrams of the (100) and {n11}B surfaces and the mechanisms discussed below.

Two distinct regions of behavior were observed on each surface with changing GaCl flow rates (see FIG. 12 left): (1) between a GaCl flow rate of 10 sccm to 30 sccm, the (100) growth rate decreased while the {n11}B growth rates remained nearly constant, and (2) above a GaCl flowrate of 30 sccm, the (100) growth rate was constant while the growth rates on the {n11}B surfaces began to increase. In Region 1, the (100) growth trend can be explained by GaCl adsorbing so strongly on the surface that it blocks the adsorption of As-containing species and arrests the surface reaction. This mechanism is consistent with the observed increase in the (100) growth rate at high temperatures (see FIG. 14), because higher temperatures increase the rate of GaCl desorption and speed up the surface kinetics leading to GaCl consumption by reducing As-site blocking. The near-constant trend in the {n11}B growth rates in Region 1 indicates that a similar competitive adsorption mechanism is not present on the facets, and that the growth rate is limited by As-containing species. AsH₃-limited growth is consistent with the observed temperature behavior on the {n11}B surfaces (see FIG. 14) because high temperatures increase desorption of reactants from the surface.

The role of AsH₃ in the Region 1 growth trends is confirmed by the data in FIG. 12 (right), which show that the growth rate increases rapidly on all surfaces with increasing AsH₃ flow rate. At an AsH₃ flow rate of 50 sccm, a crossover was observed in the (100) and {211}B growth rates, which suggests that increasing AsH₃ drives the growth reaction and suppresses GaCl competitive adsorption on (100) by consuming GaCl on the surface. This effect means that increasing the AsH₃ flow rate shifts the observed trends in Region 1 toward the upper right of the growth rate vs GaCl flow rate plot (see FIG. 12 (left)) so that higher GaCl flow rates are needed to achieve the same planarization growth behavior and a high AsH₃/GaCl ratio is detrimental to planarization by HVPE. On the other hand, decreasing the AsH₃ flow rate to 17 sccm improved the planarization efficiency, likely because low AsH₃ partial pressure exacerbates the GaCl competitive adsorption mechanism on the (100) surface. Unfortunately, a 50% reduction in the AsH₃ flow rate resulted in a >60% reduction in the growth rate on all planes, so further reduction of AsH₃ to achieve higher planarization efficiencies could result in prohibitively low growth rates for any practical use.

The absence of the GaCl competitive adsorption effect on the {n11}B surfaces indicates that the difference between the GaCl adsorption characteristics on the {n11}B and (100) surfaces is a key factor driving planarization of these faceted substrates in Region 1. The specific reason for the difference in adsorption behavior cannot be concluded from this study, but one potential cause is that adsorption of GaCl on {n11}B is weaker, resulting in more favorable GaCl desorption and less site blocking. Differences in the steric effects at the surface, i.e., effects of the bond orientations of the surface relative to the gas-phase reactants on the favorability of a kinetic mechanism, could also play a role by impacting the incorporation of the adsorbed species and their interactions with the vapor phase. A third possibility is that the activation energy for the reduction reaction could be different on the {n11}B surfaces, but the activation energy for reduction is likely low on all planes due to the hydride-enhanced mechanism, so the relative difference is likely small.

In Region 2 (see FIG. 12), a different reduction mechanism becomes prevalent, resulting in different behavior. Beyond 30 sccm of GaCl, the {n11}B growth rates increased with GaCl. This is consistent with the onset of a GaCl self-reduction mechanism where vapor-phase GaCl reduces adsorbed GaCl, forming volatile GaCl₃. The growth rate becomes dependent on GaCl because GaCl acts as a self-reducing agent in this regime. The (100) growth rate does not exhibit this increasing trend in Region 2 (see FIG. 12), indicating the self-reduction mechanism is not favorable on this surface under these conditions. The growth rate becomes constant above GaCl=30 sccm, which can be attributed to passivation of the (100) surface by the excess GaCl, which results in growth that is limited by diffusion of the reactant species from the (100) to the {n11} surfaces as opposed to GaCl reaction-limited kinetics. The difference in behavior compared to the {n11}B planes suggests that the GaCl surface concentration on (100) did not reach a sufficient level to facilitate the self-reduction mechanism. It is noted that the characteristic increase in growth rate at a GaCl flow rate of 50 sccm was observed during growth on a planar (100) substrate (see FIG. 13b), which suggests that the diffusion of material to the facet faces changes the onset of the self-reduction mechanism on the (100) surface for a faceted substrate. Suppression of the (100) growth rate over a wider range of GaCl flow rates than expected from planar growth behavior enhances the growth rate differences.

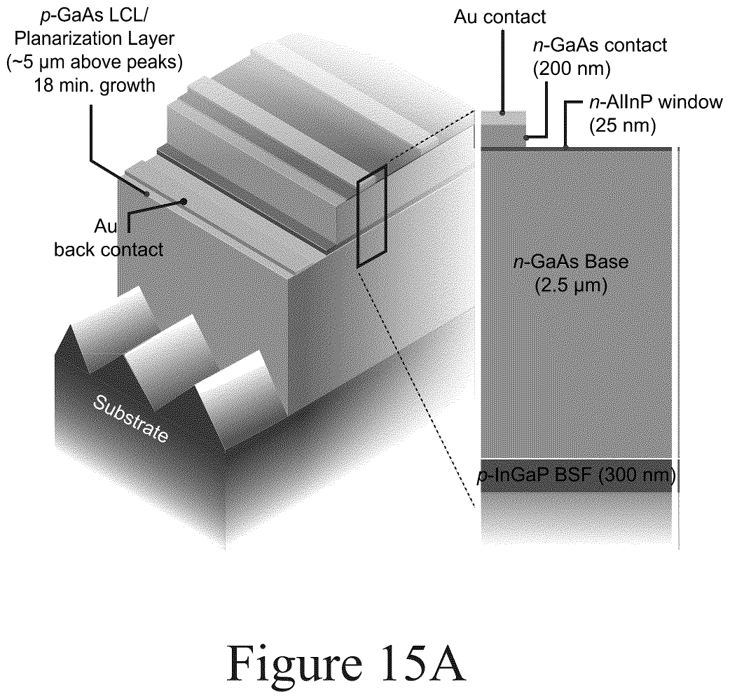

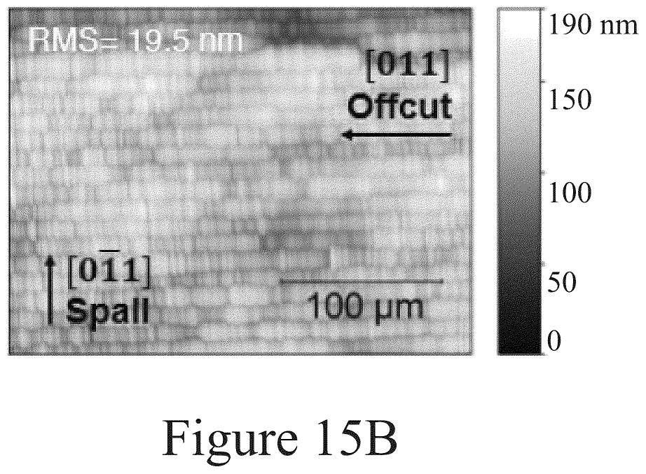

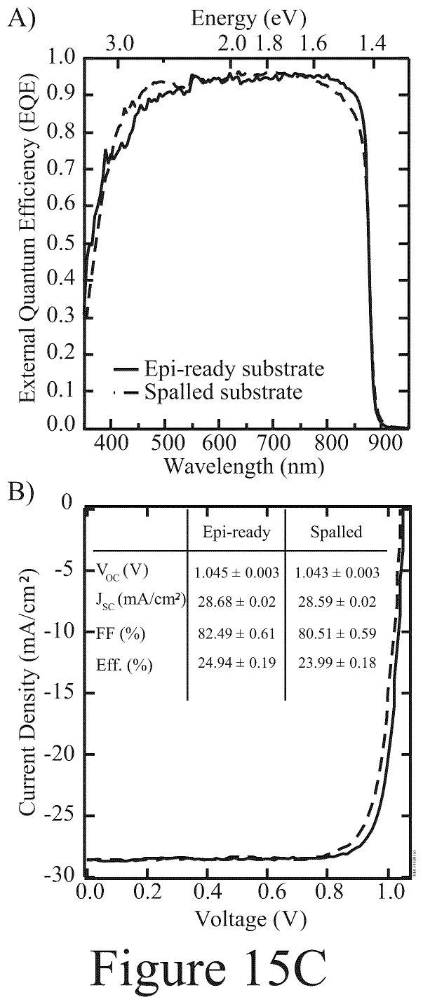

Demonstration of Solar Cell Growth After Planarization: Understanding the growth mechanisms that control planarization enables the production of planar devices on faceted substrates. A single-junction GaAs solar cell device was grown on a planarized surface to demonstrate that HVPE-planarized, spalled substrates are essentially equivalent to polished, epitaxy-ready substrates. A solar cell is an advantageous test structure for determining material quality because its performance metrics are sensitive to the average defect density over a large area. An upright, rear heterojunction (RHJ) structure with a 0.25-cm² cell area was grown and compared the performance under 1-sun illumination with a simulated AM1.5 g spectrum to that of a control device grown on a traditional, epitaxy-ready, (100)-oriented substrate. FIG. 15a illustrates the device structure with planarization over the ˜3-μm-tall facets observed on the spalled substrate. Planarization growth condition using a GaCl flow rate of 15 sccm and a AsH₃ flow rate 34 sccm, which had an η_{P}=1.4 in previous tests (see FIG. 12 (left)), was used to planarize the facets, and this planarization layer doubled as a lateral conduction layer (LCL) for the back contact. The planarizing/LCL layer was grown for 18 minutes to fill in the facet troughs and achieve approximately between 3 μm and 5 μm of total growth above the facet peaks for sufficient lateral conduction through the layer. A ˜5-μm-thick LCL was grown for the epitaxy-ready-substrate control sample using the same growth conditions.

Test structures having only the LCL were grown with these planarization conditions on spalled and epitaxy-ready substrates to compare the expected surface roughness before device growth. FIG. 15b illustrates a confocal microscopy height map of the planarized surface of the spalled test sample after growth. The planarized surface had residual ridges with periodicity consistent with the original facet ridge orientation that were approximately 20 nm deep. There was also a shallow wavelike morphology along the length of the ridges that was in the direction of the original wafer offcut step direction. The RMS roughness of the LCL surface after growth on an epitaxy-ready substrate was 5.5 nm over a 286 μm×215 μm area, and the RMS roughness of the planarized LCL layer was approximately 19.5 nm over a the same 286 μm×215 μm area, about 3.4 times the roughness of the control surface. The active layers of the cell structure used identical growth conditions on each substrate and were not adjusted for growth on the planarized surface.

FIG. 15c illustrates the external quantum efficiency (EQE) of the control and planarized solar cell devices. In the planarized cell, increased EQE was observed at short wavelengths and a slight reduction in EQE at long wavelengths compared to the control. This behavior can be traced to thickness variation between the devices and is therefore likely not a result of decreased minority-carrier diffusion length. Table 4 summarizes the layer thicknesses modeled from reflectance data of each device. The GaAs base layer in the planarized device is approximately 700 nm thinner than that of the control, and a thinner base limits the collection of carriers generated near the back of the device by long wavelength photons. In turn, the increased transmission through the thinner device causes the observed EQE behavior in an upright RHJ device structure. The thinner window layer also affects the carrier collection at short wavelengths due to differences in parasitic absorption in the window.

TABLE 4
Device layer thicknesses modeled from reflectance
measurements of the solar cells

| | | |
|---|---|---|
| Layer | Control Device | Planarized Device |

| | | | | |
|---|---|---|---|---|
| AlInP Window | 28 | nm | 23 | nm |
| GaAs Base | 3.04 | μm | 2.34 | μm |
| InGaP Back | 0.33 | μm | 0.17 | μm |
| Surface Field | | | | |

FIG. 15d illustrates the current density-voltage (J-V) curves of the devices. The performance metrics listed in the figure (short circuit current density (J_{SC}), open circuit voltage (V_{OC}), fill factor (FF), and efficiency) show that there is only a minor difference between the performance of the device grown after planarization and the one grown on a virgin epitaxy-ready substrate. The V_{OC} of the devices is within the measurement error, indicating that there was no significant loss in material quality after growth on the spalled surface and that the residual surface roughness after planarization does not adversely affect the growth or quality of the active device layers. This study shows that planarization is viable for the direct use of lower-cost substrates for solar cells without significant loss in performance. In addition, these results demonstrate the potential of applying growth morphology control via HVPE to the growth of any III-V device on a non-planar surface.

### Methods

Spalled Substrate Preparation and Characterization: This work used (100)-oriented, Si-doped (n-type) GaAs substrates with a 6° offcut toward the Ga-terminated {111} A plane. Controlled spalling was carried out using an electroplated nickel stressor layer that was deposited across the full 2 inch wafer surface using a Ni—P electrolyte (0.6 M NiCl₂×6 H₂O, 5 mM H₃PO₃) and a nickel counter electrode. Electroplating was performed galvanostatically with 15 mA/cm² current density for 18 or 20 min. The peeling force was applied in the [0 1̅ 1] direction using a linearly actuated roller to produce facets with {n11}B-type surfaces. The surface facet morphology was analyzed using confocal laser microscopy and 2D line profiles were extracted to determine the character of the facet surface before growth. Atomic force microscopy (AFM) with a resolution of 1024 points per line and a scan rate of 1 Hz was also used to determine the surface roughness of a facet face.

Planarization Growth and Analysis: HVPE growth was performed at 650° C., unless otherwise specified, in the hydride-enhanced growth regime. A two-growth-chamber dynamic HVPE (D-HVPE) reactor described previously was used for the growth. Zn-doped GaAs was used as the planarization material, and thin Al_{0.2}Ga_{0.8}As marker layers (˜70-150 nm thickness) were deposited between GaAs planarization layers by moving the wafer between the chambers of the D-HVPE system. These marker layers had a negligible contribution to planarization due to their thickness and enabled observation of the growth surface evolution in cross-sectional SEM. A total of five GaAs planarization layers were grown to track the growth progression, and the growth time was varied based on growth rates to achieve a 1-2 μm layer thickness. This thickness enabled appropriate resolution of the growth progression for analysis. The GaCl flow rate (varied by changing the HCl flow rate over the liquid Ga source) and the AsH₃ flow rate were varied to study their effect on the growth rate. One flow rate was varied for each study; all other growth flow rates were kept constant. Table 3 summarizes the conditions used for the growth studies, indicating the values of the relevant flows held constant.

The growth behavior was analyzed using cross-sectional SEM in secondary-electron imaging mode. The SEM imaging contrast between AlGaAs and GaAs allowed observation and measurement of the evolution of the {n11}B facet planes and evolved (100) surface throughout the five-marker-layer growth. The growth rates on each observed plane were measured perpendicular to the surface within each planarizing GaAs layer by fitting a line with a slope that matched the inclination of the {n11}B or (100) surfaces along the AlGaAs marker layer and measuring the GaAs thickness between two layers. Planarized layers that were grown after the facet troughs were filled in were not included because they exhibit different growth rate behavior without the presence of the facet trough. The measurements were performed for 6-10 facets across each sample to determine an average growth rate and 95% confidence interval for the average growth rate at each growth condition.

Solar Cell Device Fabrication and Testing: Upright rear heterojunction solar cell devices were grown on a planarized spalled substrate to test the material quality after planarization. A Zn-doped GaAs planarizing buffer layer (without AlGaAs marker layers) was grown over the facets and acted as an LCL at the back of the device. Confocal laser optical profilometry was performed on test samples grown using the planarizing LCL condition on both a faceted and planar substrate to assess the RMS roughness of the surface available for device growth on each substrate. Plane-tilt subtraction was performed before measuring the roughness. After growth, 0.25-cm²-area, 1-sun devices were processed using standard photolithographic techniques, and an antireflection coating consisting of MgF₂—ZnS—MgF₂ was deposited via sputtering. The performance of a device grown on the planarized substrate was compared to that of an equivalent device grown on a traditional epitaxy-ready substrate. External quantum efficiency (EQE) was measured for wavelengths 350-950 nm. The current density-voltage (J-V) characteristics were measured under a simulated AM1.5 g spectrum, and the short circuit current density (J_{SC}), open circuit voltage (V_{OC}), fill factor (FF), and efficiency were compared between the planarized and control devices.

### EXAMPLES

Example 1. A method for smoothing a surface, the method comprising: a first depositing onto a first surface of a first layer, resulting in the forming of a second layer on the first surface, wherein: the first surface has a first surface feature height, the second layer comprises a second surface having a second surface feature height that is less than the first surface feature height, the first depositing is performed using hydride vapor phase epitaxy (HVPE), the first layer comprises a first III-V alloy or an alloy comprising a Group IV element, and the second layer comprises a second III-V alloy or an alloy comprising a Group IV element.

Example 2. The method of Example 1, wherein the Group IV element of the first layer comprises at least one of at least one of carbon, silicon, germanium, tin, or lead.

Example 3. The method of either Example 1 or Example 2, wherein the Group IV element of the second layer comprises at least one of at least one of carbon, silicon, germanium, tin, or lead.

Example 4. The method of any one of Examples 1-3, wherein: the first III-V alloy comprises a first Group III element comprising at least one of boron, aluminum, gallium, indium, or thallium, and the first III-V alloy comprises a first Group V element comprising at least one of nitrogen, phosphorus, arsenic, antimony, or bismuth.

Example 5. The method of any one of Examples 1-4, wherein the first III-V alloy comprises at least one of GaAs or InP.

Example 6. The method of any one of Examples 1-5, wherein: the second III-V alloy comprises a second Group III element comprising at least one of boron, aluminum, gallium, indium, or thallium, and the second III-V alloy comprises a second Group V element comprising at least one of nitrogen, phosphorus, arsenic, antimony, or bismuth.

Example 7. The method of any one of Examples 1-6, wherein the second III-V alloy comprises at least one of GaAs, GaInP, AlGaAs, AlInP, AlGaInP, GaInNAs, or GaInNAsSbBi.

Example 8. The method of any one of Examples 1-7, wherein the first surface feature height is between 1 μm and 100 or between 1 μm and 20 μm or between 4 μm and 8 μm (for spalled surfaces) or between 2 μm and 8 μm (for cut surfaces).

Example 9. The method of any one of Examples 1-8, wherein the second surface feature height is less than or equal to about 1 μm or less than or equal to about 0.1 μm.

Example 10. The method of any one of Examples 1-9, wherein the first depositing is performed using at least one of a first precursor comprising the first Group III element, a second precursor comprising the first Group V element, and a first carrier gas.

Example 11. The method of any one of Examples 1-10, wherein the first depositing is performed at a first pressure between 0.01 atm and 2.0 atm or between 0.15 atm and 1.2 atm (absolute pressures).

Example 12. The method of any one of Examples 1-11, wherein the first depositing is performed at a first temperature between 500° C. and 800° C., or between 600° C. and 700° C.

Example 13. The method of any one of Examples 1-12, wherein the first precursor and the second precursor are supplied to provide a first ratio of the first Group V element to the second Group III element (V/III) is between 0.1 (0.1 to 1.0) and 20 (20 to 1.0), or between 0.3 and 13, or between 0.3 and 10, or between 2 and 13.

Example 14. The method of any one of Examples 1-13, wherein the first surface is characterized by a substrate having an orientation comprising at least one of a (100) orientation, a 211 orientation, or steps on spalled substrate having a (110) orientation.

Example 15. The method of any one of Examples 1-14, wherein the first surface is characterized by a (100) orientation, a (111) orientation, a (211) orientation, a (311) orientation, or a (110) orientation.

Example 16. The method of any one of Examples 1-15, wherein the first surface has an offcut between zero degrees and 30 degrees, or between zero degrees and 15 degrees,

Example 17. The method of any one of Examples 1-16, wherein the first surface is characterized by an irregular starting morphology (for cut surfaces), a regularly faceted surface (for spalled surfaces), an irregularly faceted surface (different facet heights in different places, different orientations in different places), or a surface containing river lines or arrest lines close to a wafer edge.

Example 18. The method of any one of Examples 1-17, wherein the first surface has a substantially corrugated surface comprising at least one of {n11} facets or {110} facets and n is an integer value between 1 and 5, inclusively.

Example 19. The method of any one of Examples 1-18, wherein the facets comprise {211} facets.

Example 20. The method of any one of Examples 1-19, wherein the irregular starting morphology comprises randomly oriented and sized features containing more than 3 types of planes.

Example 21. The method of any one of Examples 1-20, further comprising: a second depositing onto the second surface of the second layer, resulting in the forming of a third layer on the second surface, wherein: the third layer comprises a third surface having a third surface feature height that is less than the second surface feature height, the second depositing is performed using hydride vapor phase epitaxy (HVPE), and the third layer comprises a third III-V alloy.

Example 22. The method of any one of Examples 1-21, wherein: the third III-V alloy comprises a third Group III element comprising at least one of boron, aluminum, gallium, indium, or thallium, and the third III-V alloy comprises a third Group V comprising at least one of nitrogen, phosphorus, arsenic, antimony, or bismuth.

Example 23. The method of any one of Examples 1-22, wherein the third III-V alloy further comprises a Group IV element.

Example 24. The method of any one of Examples 1-23, wherein the third III-V alloy comprises at least one of GaAs, GaInP, AlGaAs, AlInP, AlGaInP, GaInNAs, or GaInNAsSbBi.

Example 25. The method of any one of Examples 1-24, wherein the second depositing is performed at a second pressure between 0.8 atm and 1.2 atm (nominal performed at about 1.0 atm).

Example 26. The method of any one of Examples 1-25, wherein the second depositing is performed at a second temperature between 500° C. and 800° C., or between 600° C. and 700° C.

Example 27. The method of any one of Examples 1-26, wherein the second depositing is performed using at least one of a third precursor comprising the third Group III element, a fourth precursor comprising the third Group V element, and a second carrier gas.

Example 28. The method of any one of Examples 1-27, wherein the third precursor and the fourth precursor are provided at a second ratio of the third Group V element to the third Group III element (V/III) that is greater the first ratio of the first Group V element to the second Group III element.

Example 29. A method of any one of Examples 1-28, wherein the order of the first depositing and the second depositing is reversed.

Example 30. A composition comprising: a first layer comprising a surface characterized by a first surface feature height; and a second layer comprising a surface characterized by a second surface feature height, wherein: the first layer is positioned adjacent to and in contact with the second layer, and the second surface feature height is less than the first surface feature height.

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A method for smoothing a surface, the method comprising:
a first depositing onto a first surface of a first layer, resulting in the forming of a second layer on the first surface, wherein:
the first surface has a first surface feature height,
the second layer comprises a second surface having a second surface feature height that is less than the first surface feature height,
the first depositing is performed using hydride vapor phase epitaxy (HVPE),
the first layer comprises a first III-V alloy or an alloy comprising a Group IV element, and
the second layer comprises a second III-V alloy or an alloy comprising a Group IV element.

2. The method of claim 1, wherein:
the first III-V alloy comprises a first Group III element comprising at least one of boron, aluminum, gallium, indium, or thallium, and
the first III-V alloy comprises a first Group V element comprising at least one of nitrogen, phosphorus, arsenic, antimony, or bismuth.

3. The method of claim 4, wherein the first III-V alloy comprises at least one of GaAs or InP.

4. The method of claim 1, wherein:
the second III-V alloy comprises a second Group III element comprising at least one of boron, aluminum, gallium, indium, or thallium, and
the second III-V alloy comprises a second Group V element comprising at least one of nitrogen, phosphorus, arsenic, antimony, or bismuth.

5. The method of claim 4, wherein the second III-V alloy comprises at least one of GaAs, GaInP, AlGaAs, AlInP, AlGaInP, GaInNAs, or GaInNAsSbBi.

6. The method of claim 1, wherein the first surface feature height is between 1 μm and 100 μm.

7. The method of claim 6, wherein the first surface feature height is between 1 μm and 20 μm.

8. The method of claim 1, wherein the second surface feature height is less than or equal to about 1 μm.

9. The method of claim 8, wherein the second surface feature height is between 0.1 μm and 1 μm.

10. The method of claim 1, wherein the first depositing is performed using at least one of a first precursor comprising the first Group III element, a second precursor comprising the first Group V element, and a first carrier gas.

11. The method of claim 1, wherein the first depositing is performed at a first pressure between 0.01 atm and 2.0 atm.

12. The method of claim 1, wherein the first depositing is performed at a first temperature between 500° C. and 800° C.

13. The method of claim 11, wherein the first precursor and the second precursor are supplied to provide a first ratio of the first Group V element to the second Group III element (V/III) is between 0.1 (0.1 to 1.0) and 20 (20 to 1.0).

14. The method of claim 1, wherein the first surface is characterized by a substrate having an orientation comprising at least one of a (100) orientation, a 211 orientation, or steps on a spalled substrate having a (110) orientation.

15. The method of claim 1, wherein the first surface is characterized by a (100) orientation, a (111) orientation, a (211) orientation, a (311) orientation, or a (110) orientation.

16. The method of claim 1, wherein the first surface has an offcut between zero degrees and 30 degrees.

17. The method of claim 1, wherein the first surface has a substantially corrugated surface comprising at least one of {n11} facets or {110} facets and n is an integer value between 1 and 5, inclusively.

18. The method of claim 17, wherein the facets comprise {211} facets.

19. The method of claim 1, further comprising:
a second depositing onto the second surface of the second layer, resulting in the forming of a third layer on the second surface, wherein:
the third layer comprises a third surface having a third surface feature height that is less than the second surface feature height,
the second depositing is performed using hydride vapor phase epitaxy (HVPE), and
the third layer comprises a third III-V alloy.

20. A composition comprising:
a first layer comprising a surface characterized by a first surface feature height; and
a second layer comprising a surface characterized by a second surface feature height, wherein:
the first layer is positioned adjacent to and in contact with the second layer, and
the second surface feature height is less than the first surface feature height.
